(19) United States
(12) Patent Application Publication
(10) Pub. No.: US 2007/0291261 A1
(43) Pub. Date: Dec. 20, 2007

(54) Exposure apparatus, exposure method, and device manufacturing method

(75) Inventor: Naoyuki Kobayashi, Fukaya-shi (JP)

Correspondence Address: OLIFF & BERRIDGE, PLC, P.O. BOX 320850, ALEXANDRIA, VA, 22320-4850, US

(73) Assignee: NIKON CORPORATION, TOKYO (JP)

(21) Appl. No.: 11/785,011

(22) Filed: Apr. 13, 2007

Related U.S. Application Data
(60) Provisional application No. 60/905,818, filed on Mar. 9, 2007.

(30) Foreign Application Priority Data
Apr. 14, 2006 (JP) 2006-112015

(51) Int. Cl. G01J 1/00; G03F 1/00

(52) U.S. Cl. 356/213; 430/5

(57) ABSTRACT

A substrate is exposed by a first operation wherein detection light is directed upon a specified reference surface to detect surface positional information of a reference surface based on results of reception of detection light through the reference surface and by a second operation wherein detection light is directed upon a specified area of a first surface of a first mask to detect surface positional information of area based on results of reception of detection light through a first surface. The second operation is implemented a plurality of times for each of the plurality of areas of the first surface, and the first operation is implemented for each second operation before the second operation.

### CROSS-REFERENCE TO RELATED APPLICATION

This application is a non-provisional application claiming benefit of provisional application No. 60/905,818, filed Mar. 9, 2007, and claims priority to Japanese Patent Application No. 2006-112015, filed Apr. 14, 2006, the contents of which are incorporated herein by reference.

### BACKGROUND OF THE INVENTION

1. Field of the Invention

The present invention relates to exposure method for exposing substrate with mask pattern, exposure apparatus, and device manufacturing method.

2. Description of Related Art

Exposure apparatus is used in photolithographic processes during the manufacture of microdevices such as semiconductor devices to project the image of a mask pattern on to a photosensitive substrate through a projection optical system. If the surface on which the mask pattern is formed deflects because of the mask weight (self weight) and so on, the projection state of the pattern image may change, and the substrate may not be exposed satisfactorily. Acquisition of surface positional information of the surface on which the mask pattern is formed is effective in exposing the substrate satisfactorily. An example of the technique of acquiring surface positional information of the surface on which mask pattern is formed by using sensors is disclosed in Japanese Unexamined Patent Application, First Publication No. 2004-356290.

If the positional information of a plurality of detection points on the pattern-formed surface is detected using sensors to acquire the surface positional information of the surface on which a mask pattern is formed, error may occur between the detecting operations due to zero point drift of the sensor and so on. This may lead to not acquiring accurately the surface positional information of the pattern-formed surface.

Moreover, to associate the acquired surface positional information and the projection state of the pattern image, in addition to the operation of acquiring the surface positional information of pattern-formed surface of mask, an operation to acquire the projection state of pattern image using that mask may be necessary. Operations to acquire the projection state of pattern image using mask may include, for example, the operation to measure the pattern shape on the test-exposed substrate using mask. The general procedure to manufacture the device is to use a plurality of masks and sequentially project a plurality of pattern images on the substrate. However, when the operation to acquire surface positional information and the operation to acquire projection state are implemented for each of the plurality of masks, the utilization rate of the exposure apparatus drops, possibly leading to a reduction in the throughput.

A purpose of some aspects of the invention is to provide an exposure method that can expose a substrate satisfactorily, an exposure apparatus, and a device manufacturing method using the exposure method and the exposure apparatus that can acquire accurately and with good efficiency the surface positional information of surface on which the mask pattern is formed.

### SUMMARY OF THE INVENTION

According to a first aspect of the present invention, there is provided an exposure method including: detecting, based on a reception result of a detection light from a reference surface on which the detection light is directed, a first information including a surface positional information of the reference surface; detecting, based on a reception result of the detection light from a first surface of a first mask on which a pattern is formed, a second information including a surface positional information of the first surface, the first surface including a plurality of areas each on which the detection light is directed, the detection of the second information being executed for respective the areas, the detection of the first information being executed before the detection for the areas; and exposing a substrate with the pattern of the first mask.

According to the first aspect of the invention, the surface positional information of surface with mask pattern formed thereupon can be acquired with good efficiency and precision; and the substrate can be satisfactorily exposed using the acquired surface positional information.

According to a second aspect of the present invention, there is provided an exposure method including: detecting a first information including surface positional information of a reference surface of a reference mask whereupon a pattern is formed; obtaining a reference correction value for exposing a substrate in desired state via the reference mask; detecting a second information including surface positional information of a first surface of a first mask; obtaining a first correction value for exposing the substrate in desired state via the first mask based on the first information, the second information, and the reference correction value; and exposing the substrate with pattern formed on the first surface of the first mask based on exposure condition adjusted based on the first correction value.

According to the second aspect of the invention, the surface positional information of surface with mask pattern formed thereupon can be acquired with good efficiency and precision; and the substrate can be satisfactorily exposed using the acquired surface positional information.

According to a third aspect of the present invention, a device manufacturing method is provided using the exposure method of the above aspect.

According to the third aspect of the invention, device can be manufactured using an exposure method that exposes the substrate satisfactorily.

According to a fourth aspect of the present invention, there is provided an exposure apparatus that exposes a substrate with a pattern formed on a first surface of a first mask, the exposure apparatus including: a holding member that holds the first mask; a first detection apparatus that directs a detection light onto a specified area of a first surface of the first mask held by the holding member via a first opening formed on the holding member and directs the detection light onto a specified reference surface, surface positional information of the area being capable of being detected based on a reception result of the detection light from the first surface, surface positional information of the reference surface based on a reception result of the detection light from the reference surface; and a control apparatus that controls the first detection apparatus to detect surface positional information of each of a plurality of areas of the first surface, and controls the detecting operation for the reference surface with the first detection apparatus such that the detecting operation is implemented in each detecting operation for the areas before the detecting operation for the areas.

According to the fourth aspect of the invention, the surface positional information of surface with mask pattern formed thereupon can be acquired with good efficiency and precision; and the substrate can be satisfactorily exposed using the acquired surface positional information.

According to a fifth aspect of the present invention, there is provided an exposure apparatus that exposes a substrate with a pattern formed on a first surface of a first mask, the exposure apparatus including: a first detection apparatus that detects surface positional information of the first surface of the first mask; a first storage apparatus that pre-stores surface positional information of a second surface whereupon a pattern of a second mask different from the first mask is formed; a second storage apparatus that pre-stores a second correction value for exposing the substrate in desired state using the second mask; and a control apparatus that determines a first correction value for exposing the substrate in desired state using the first mask based on the detection result of the first detection apparatus, the stored information in the first storage apparatus, and the stored information in the second storage apparatus.

According to the fifth aspect of the invention, the surface positional information of surface with mask pattern formed thereupon can be acquired with good efficiency and precision; and the substrate can be satisfactorily exposed using the acquired surface positional information.

According to a sixth aspect of the present invention, a device manufacturing method is provided using the exposure apparatus of the above aspect.

According to the sixth aspect of the present invention, device can be manufactured using an exposure apparatus that can expose the substrate satisfactorily.

### BRIEF DESCRIPTION OF THE DRAWINGS

FIG. 1 is a schematic configuration diagram showing the exposure apparatus related to the first embodiment.

FIG. 2 is a perspective view showing the neighborhood of the mask stage related to the first embodiment.

FIG. 3 is an exploded perspective view of FIG. 2.

FIG. 4 is a sectional cross section view showing the neighborhood of the mask stage schematically.

FIG. 5 is a schematic plan view of the mask stage viewed from the bottom.

FIG. 6 is a schematic configuration diagram showing the detection apparatus.

FIG. 7 is a side view showing the substantial parts of the detection apparatus.

FIG. 8A shows the state of the detection apparatus directing the detection light on each of the specified detection points in each area of the pattern-formed surface.

FIG. 8B shows the state of the detection apparatus directing the detection light on each of the specified detection points in each area of the pattern-formed surface.

FIG. 8C shows the state of the detection apparatus directing the detection light on each of the specified detection points in each area of the pattern-formed surface.

FIG. 9A is a side view showing the substantial parts of FIG. 8A.

FIG. 9B is a side view showing the substantial parts of FIG. 8B.

FIG. 9C is a side view showing the substantial parts of FIG. 8C.

FIG. 10 shows the state in which the detection light is directed at the detection point in the specified area of the pattern-formed surface.

FIG. 11 is a schematic diagram for explaining the detecting operation by the detection apparatus.

FIG. 12 is a flow chart showing the exposure method related to the first embodiment.

FIG. 13 is a flow chart showing the exposure method related to the second embodiment.

FIG. 14 is a flow chart showing the exposure method related to the third embodiment.

FIG. 15 shows schematically the pattern-formed surface of the reference mask and the pattern-formed surface for device manufacture.

FIG. 16 is a flowchart showing an example of the manufacturing process for a microdevice.

### DETAILED DESCRIPTION OF THE INVENTION

The exemplary embodiments of the present invention are described below referring to the drawings, but it is to be noted that the present invention is not limited to these embodiments. In the explanations below, an XYZ orthogonal coordinate system is set, and the positional relationships of various members are described with reference to this XYZ orthogonal coordinate system. Next, a predetermined direction in the horizontal plane is taken as the X-axis direction, a direction perpendicular to the X-axis direction in the horizontal plane is taken as the Y-axis direction, and a direction perpendicular both the X-axis direction and the Y-axis direction (that is vertical direction) is taken as the Z-axis direction. The direction of rotation (oblique) about the X axis, Y axis and Z axis are taken as θX, θY and θZ respectively.

### First Embodiment

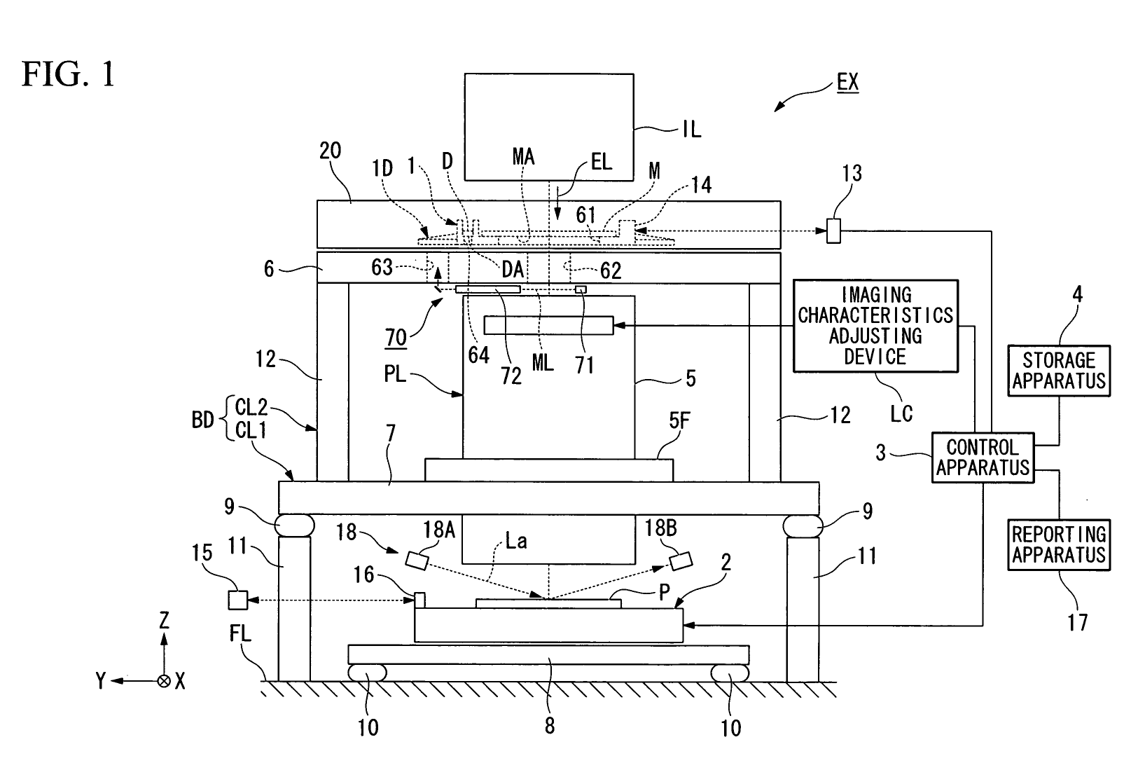

FIG. 1 is a schematic configuration showing an exposure apparatus EX related to the first embodiment. In FIG. 1, the exposure apparatus EX is provided with a mask stage 1 that can move while retaining a mask M, a substrate stage 2 that can move while retaining the substrate P, an illumination system IL that illuminates the mask M retained in the mask stage 1 with an exposure light EL, and a projection optical system PL that projects the pattern image of the mask M illuminated by the exposure light EL on the substrate P retained in the substrate stage 2. The exposure apparatus EX is further provided with a control apparatus 3 for controlling all the operations of the exposure apparatus EX, a storage apparatus 4 connected to the control apparatus 3, which memorizes all kinds of information related to the exposure process, and a reporting apparatus 17 connected to the control apparatus 3, which reports the state of operation of the exposure apparatus EX. The reporting apparatus 17 may include display devices such as liquid crystal display, light emitting devices for emitting light, and sound emitting devices for emitting sound.

Here, substrates includes may include those coated with photosensitive material (photo resist) on a base material such as semiconductor wafer including silicone wafer, for instance, and those that are coated with various kinds of film such as protective film (top coat film) different from photosensitive film. Mask includes a reticule formed with a device pattern which is reduction size projected onto the substrate. Also, in the present embodiment, the mask used may be a transparent mask or a reflecting mask.

The mask M has a specified pattern formed on a transparent plate member such as glass plate using a photo shielding film, and has a pattern-formed surface MA on which pattern is formed. This transparent mask is not limited to a binary mask on which pattern is formed with photo shielding film; for example, a half-tone type mask or a phase shift mask of the spatial frequency modulation type is also included. The control apparatus 3 illuminates the exposure light EL on the mask M retained in the mask stage 1. By illuminating the exposure light EL passing through the mask M on the substrate P through the projection optical system PL, the pattern image formed on the pattern-formed surface MA of the mask M is projected on the substrate P, and the substrate P is exposed.

In the embodiment, the exposure apparatus EX has a detection apparatus 70 that can detect the surface positional information of the pattern-formed surface MA on which the pattern of mask M is formed. The detection apparatus 70 directs the detection light ML on the pattern-formed surface MA of the mask M, and acquires surface positional information of the pattern-formed surface MA of the mask M, based on the reception results of the detection light ML from the pattern-formed surface MA.

Here, the surface positional information includes various kinds of data such as position of the surface (Z axis, and positions with respect to θX and θY), shape (unevenness), and flatness.

In the present embodiment, the mask stage 1 is provided with a reference member D having a specified reference surface DA. The detection apparatus 70 can also detect the surface positional information of the reference surface DA of the reference member D. The reference member D is formed from a material with low coefficient of linear thermal expansion, such as low-expansion glass or low-expansion ceramics. The detection apparatus 70 directs the detection light ML on the reference surface DA of the reference member D, and acquires optically the surface positional information of the reference surface DA of the reference member D, based on the reception results of the detection light ML from the reference surface DA.

In the present embodiment, the exposure apparatus EX is a scanning type exposure apparatus (so-called scanning stepper) that projects the pattern image formed in the mask M on to the substrate P while simultaneously moving the mask M and the substrate P in the specified scanning direction. In the present embodiment, the direction in which the mask M and the substrate P are simultaneously moved (scanning direction) is taken as the Y-axis direction.

The exposure apparatus EX is provided with a body BD that includes a first column CL1 mounted on the floor surface FL and a second column CL2 mounted on the first column CL1 in the clean room, for example. The first column CL1 is provided with a plurality of first supports 11 and a lens barrel base 7 supported by the first supports 11 with vibration isolation apparatuses 9. The second column CL2 is provided with a plurality of second supports 12 mounted on the lens barrel base 7, and a mask stage base 6 supported by these second supports 12.

The illumination system IL illuminates the specified illumination area on the mask M with the exposure light EL of uniform luminance distribution. The exposure light EL emitted from the illumination system IL, may be bright lines (g-rays, h-rays, i-rays) emitted from a mercury lamp, for example, or deep ultraviolet light (DUV light) such as KrF excimer laser light (wavelength 248 nm), vacuum ultraviolet light (VUV light) such as ArF excimer laser light (wavelength 193 nm) or an F₂ laser light (wavelength 157 nm). In the present embodiment, ArF excimer laser light is used.

The mask stage 1 can move in the X-axis, Y-axis, and θZ directions on the mask stage base 6 with the mask M in the retained state when driven by the mask stage drive device 1D including an actuator such as linear motor. The mask stage 1 is contactlessly supported on the upper surface (guide surface) of the mask stage base 6 by an air bearing (air pad). The mask stage 1 has a first opening 61 to pass through the exposure light EL when exposing the substrate P. The mask stage base 6 has a second opening 62 to pass through the exposure light EL. The exposure light EL illuminating the pattern-formed surface MA of mask M and emitted from the illumination system IL is incident on the projection optical system PL after passing through the first opening 61 of the mask stage 1 and the second opening 62 of the mask stage base 6.

Also, a third opening 63 is provided in the mask stage base 6 at a position different from the second opening 62 to pass through the detection light ML of the detection apparatus 70. Furthermore, a fourth opening 64 is provided in the mask stage 1 at a position different from the first opening 61 to pass through the detection light ML of the detection apparatus 70.

A counter mass 20 is provided in the mask stage base 6. It moves in a counter direction against that of the mask stage 1 (for example, in the −Y direction), depending on the movement of the mask stage 1 in either one direction along the Y-axis (for example in the +Y direction). The counter mass 20 is contactlessly supported on the upper surface of the mask stage base 6 with a self weight canceling mechanism including an air pad. The counter mass 20 of the present embodiment is installed such that it surrounds the mask stage 1. The positional information of mask stage 1 (and mask M) is measured by a laser interferometer 13. The laser interferometer 13 measures the positional information of the mask stage 1 using a reflecting surface 14 provided on the mask stage 1. The control apparatus 3 drives the mask stage drive device 1D based on the measurement results of the laser interferometer 13, and controls the position of mask M retained in the mask stage 1.

The projection optical system PL projects the pattern image of the mask M on the substrate P at the specified projection magnification. It has a plurality of optical elements, and these optical elements are retained in a lens barrel 5. The lens barrel 5 has a flange SF. The projection optical system PL is supported by the lens barrel base 7 through the flange SF. The projection optical system PL of the present embodiment has a reduction system with projection magnification for example of ¼, ⅕, ⅛ and so on, and reduction image of the pattern is formed on the exposure area on the substrate. The projection optical system PL may be either a reduction system, an equal magnification system or a magnification system. Also, the projection optical system PL may be a dioptric system that does not include reflecting optical elements, a reflecting system that does not include diffraction optical elements, or it may be a catadioptric system that includes reflecting optical elements and diffraction optical elements. The projection optical system PL may form either an inverted image or an erect image.

The projection optical system is provided with an imaging characteristics adjusting device LC that can adjust the imaging characteristics (projection state) of the projection optical system PL, such as the one disclosed for example in Japanese Unexamined Patent Application, First Publication No. S60-78454, Japanese Unexamined Patent Application, First Publication No. H11-195602, PCT International Publication No. WO 2003/65428. The imaging characteristics adjusting device LC includes an optical element drive unit capable of moving some of the plurality of optical elements in the projection optical system PL. The optical element drive unit can make a specified one among the plurality of optical elements in the projection optical system PL be moved in a direction of the optical axis (Z-axis direction) or be inclined relative to the optical axis. By moving a specified one among the plurality of optical elements in the projection optical system PL, the imaging characteristics adjusting device LC can adjust the imaging characteristics (projection state) including various aberrations (e.g., a projection magnification ratio, a distortion and a spherical aberration) and an image plane position (focus position) of the projection optical system PL. Furthermore, as the imaging characteristics adjusting device LC, it may be possible to provide a pressure regulating mechanism for regulating the pressure of a gas present in a space between some of the optical elements held within the lens barrel. The imaging characteristics adjusting device LC is connected to the control apparatus 3 and is controlled by the control apparatus 3.

The substrate stage 2 has a substrate holder that holds the substrate P. By driving the substrate stage drive device including actuator such as linear motor, the substrate stage 2 can move with six degrees of freedom in the X-axis, Y-axis, Z-axis, θX, θY and θZ directions on the substrate stage base 8 with the substrate P held in the substrate holder. The substrate stage 2 is contactlessly supported on the upper surface (guide surface) of the substrate stage base 8 with an air bearing. The substrate stage base 8 is supported on the floor surface FL with the vibration isolation apparatuses 10. The positional information of substrate stage 2 (and by extension of the substrate P) is measured with the laser interferometer 15. The laser interferometer 15 measures the positional information related to the X-axis, Y-axis, and θZ directions of the substrate stage 2, using the reflecting surface 16 of a moving mirror provided in the substrate stage 2.

In the present embodiment, the exposure apparatus EX is provided with a focus and level detection system 18 that can detect the surface positional information of the surface of substrate P held in the substrate stage 2. The focus and level detection system 18 is provided with a project device 18A that projects the detection light La on the surface of the substrate P held in the substrate stage 2, and a light receiving device 18B that can receive the reflected light of the detection light La projected on the surface of the substrate P. It can detect the surface positional information of the surface of the substrate P, based on the reception results of the light receiving device 18B. The control apparatus 3 drives the substrate stage drive device based on the measurement results of the laser interferometer 15 and on the results of detection of the focus and level detection system 18, and controls the position of the substrate P held in the substrate stage 2.

The focus and level detection system can detect the surface positional information of the substrate P by measuring the positional information of each of the plurality of measurement points in the Z-axis direction of the substrate P, as disclosed in the U.S. Pat. No. 6,608,681, for example. The laser interferometer 15 may be used to measure the positional information of the substrate stage 2 in the Z-axis, θX and θY directions. This is disclosed in detail for example in Published Japanese Translation No. 2001-510577 of PCT International Publication (corresponding PCT International Publication No. WO 1999/28790).

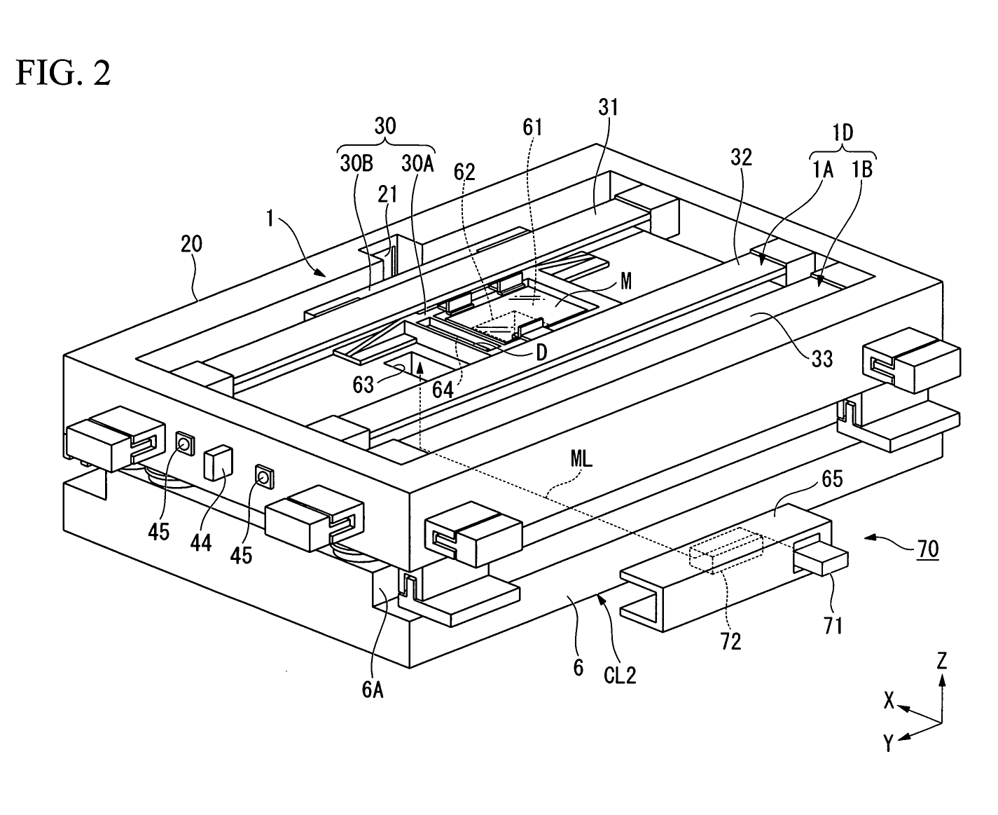

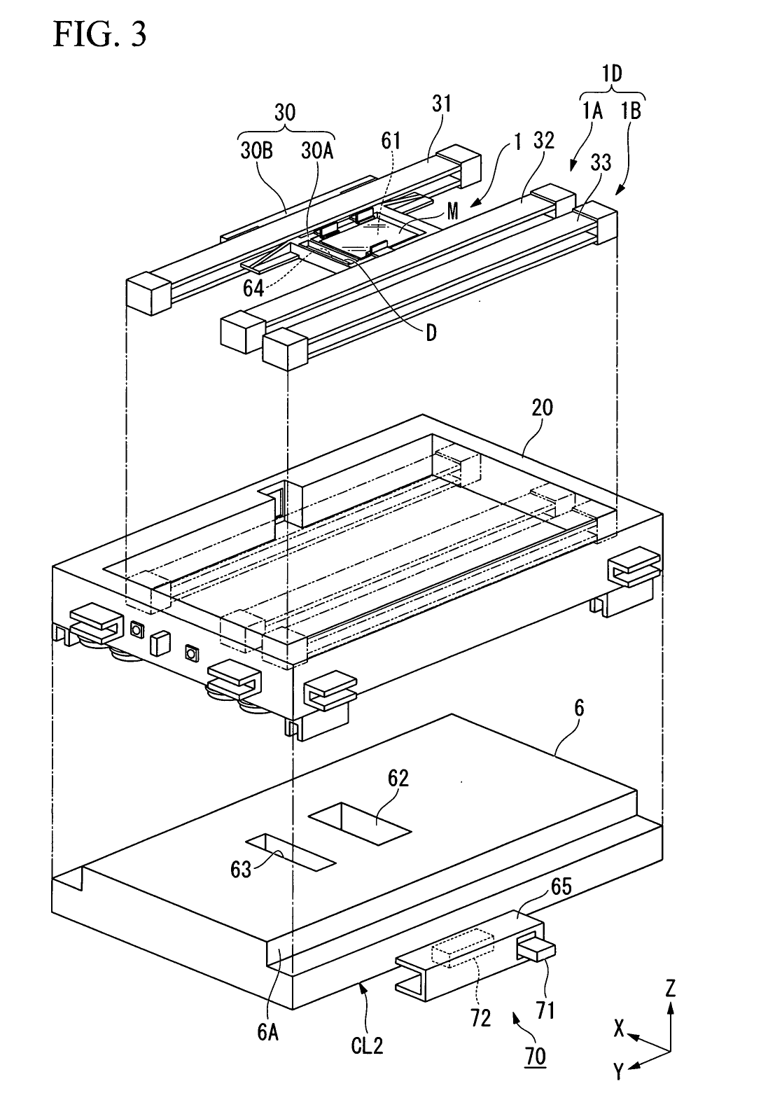

Next, the mask stage 1 is described here, referring to FIG. 2 and FIG. 3. FIG. 2 is a perspective view in the neighborhood of mask stage 1, counter mass 20, and mask stage base 6. FIG. 3 is an exploded perspective view of FIG. 2.

In FIG. 2 and FIG. 3, the mask stage 1 includes the mask stage body 30 and the various magnetic pole units and so on fixed to this mask stage body 30. The mask stage body 30 has a first member 30A of substantially rectangular shape in the XY direction, and a second member 30B provided at the end of the +X side of the first member 30A. The first opening 61 is formed substantially at the middle of the first member 30A of the mask stage 1, and the fourth opening 64 is provided at a position different from the first opening 61. In the present embodiment, the first opening 61 and the fourth opening 64 are formed side by side in the Y-axis direction.

The second member 30B is a member oriented longitudinally along the Y-axis direction. A reflecting surface (14) is formed on the side face in the +X side on which the measuring light of the laser interferometer (13) is directed. A transparent area 21 is provided in the side face on the +X side of the counter mass 20 for passing through the measuring light from the laser interferometer (13). Similarly, although not illustrated, a transparent area is also provided in the side face on the −Y side of the counter mass 20 to pass through the measuring light from the laser interferometer (13). The measuring light from the laser interferometer 13 is directed on the reflecting surface 14 provided in the side face on the −Y side of the mask stage 1.

An air bearing (air pad) is provided on the bottom surface of the mask stage body 30. The mask stage body 30 is contactlessly supported on the upper surface of the mask stage base 6 by means of an air bearing. A protruding part 6A is provided substantially at the center of the mask stage base 6 in the present embodiment. The mask stage body 30 is contactlessly supported on the upper surface of this protruding part 6A. The second opening 62 is formed substantially at the middle of the protruding part 6A of the mask stage base 6, and the third opening 63 is provided at a position different from the second opening 62. In the present embodiment, the second opening 62 and the third opening 63 are formed side by side in the Y-axis direction.

The mask stage drive device 1D is meant for driving the mask stage 1 on the mask stage base 6. The mask stage drive device 1D is provided with a first drive device 1A for driving the mask stage 1 in the Y-axis direction and for driving it slightly along the θZ direction, and with a second drive device 1B for driving the mask stage 1 slightly in the X-axis direction. The first drive device 1A has a first stator unit 31 and a second stator unit 32 mounted so as to extend in the Y-axis direction on the inside of the counter mass 20. The second drive device 1B has a third stator unit 33 disposed in the −X side of the second stator unit 32, and mounted so as to extend in the Y-axis direction on the inside of the counter mass 20.

The first and second stator units 31, 32 of the first drive device 1A each have a coil unit. The +Y-side end and the −Y-side end of the first and second stator units 31, 32, are fixed to the inner surface of the counter mass 20 via the specified fixing member. The first and second stator units 31, 32 are set apart from each other in the X-axis direction. The first member 30A of the mask stage 1 is disposed between the first stator unit 31 and the second stator unit 32. Magnetic pole units corresponding to the first and second stator units 31, 32 are set at the +X-side end and −X-side end of the first member 30A of the mask stage 1.

That is, in the present embodiment, the first drive device 1A is provided with the coil unit of first and second stator units 31, 32, and a moving magnet type linear motor including the magnetic pole unit of the mask stage 1. The control apparatus 3 performs control such that the thrust (driving force) generated by the first stator unit 31 and the magnetic pole unit corresponding thereto becomes the same as the thrust (driving force) generated by the second stator unit 32 and the magnetic pole unit corresponding thereto. Thus, it can move the mask stage 1 in a direction parallel to the Y-axis direction. Also, the control apparatus 3 can perform control such that the thrust (driving force) generated by the first stator unit 31 and the magnetic pole unit corresponding thereto differs from the thrust (driving force) generated by the second stator unit 32 and the magnetic pole unit corresponding thereto, and thus, it can move (rotate) the mask stage 1 slightly in the θZ direction.

The third stator unit 33 of the second drive device 1B has a coil unit. The +Y-side end and the −Y-side end of the third stator unit 33 are connected to the inside surface of the counter mass 20 through the specified fixing member. The third stator unit 33 is disposed at the −X-side of the second stator unit 32. Permanent magnet corresponding to the third stator unit 33 is set at the −X-side end of the mask stage 1.

Electromagnetic force (Lorentz force) is generated in the X-axis direction because of the electromagnetic interaction between the magnetic field formed by the permanent magnet provided in the mask stage 1 and the electric current flowing through the coil of the third stator unit 33. The reactive force against this Lorentz force becomes the drive force that drives the mask stage 1 in the X-axis direction.

That is, in the present embodiment, the second drive device 1B is provided with the coil unit of the third stator unit 33, and a moving magnet type voice coil motor including a permanent magnet of the mask stage 1. The control apparatus 3 can move the mask stage 1 slightly in the X-axis direction using the third stator unit 33 and the permanent magnet corresponding thereto.

In this way, the mask stage 1 is installed such that it can move with three degrees of freedom in the X-axis, Y-axis and θZ directions using the mask stage drive device 1D including the first and second drive devices 1A, 1B.

The counter mass 20 is a rectangular-shaped (shape of frame) member with an opening in which the mask stage 1 can be disposed. It is movably disposed on the upper surface of the mask stage base 6 so as to cancel out the reaction that occurs when the mask stage 1 is moved. The counter mass 20 is a rectangular-shaped (shape of frame) member with an opening in which the mask stage 1 can be disposed. It is movably disposed on the upper surface of the mask stage base so as to cancel out the reaction that occurs when the mask stage 1 is moved.

The detection apparatus 70 can also optically detect the surface positional information of the specified surface. The detection apparatus 70 is provided with a sensor unit 71 that can project the detection light ML for the specified surface and can also receive the detection light ML through that specified surface, and an optical unit 72 that passes through the detection light ML. In the present embodiment, at least a part of the detection apparatus 70 is supported by the second column CL2. As shown in FIG. 2, a support mechanism 65 is installed in a part of the second column CL2 for supporting the detection apparatus 70. At least a part of the detection apparatus 70 including the sensor unit 71 and the optical unit 72 is supported by the support mechanism 65. At least a part of the detection apparatus 70 may be supported by a specified member apart from the second column CL2.

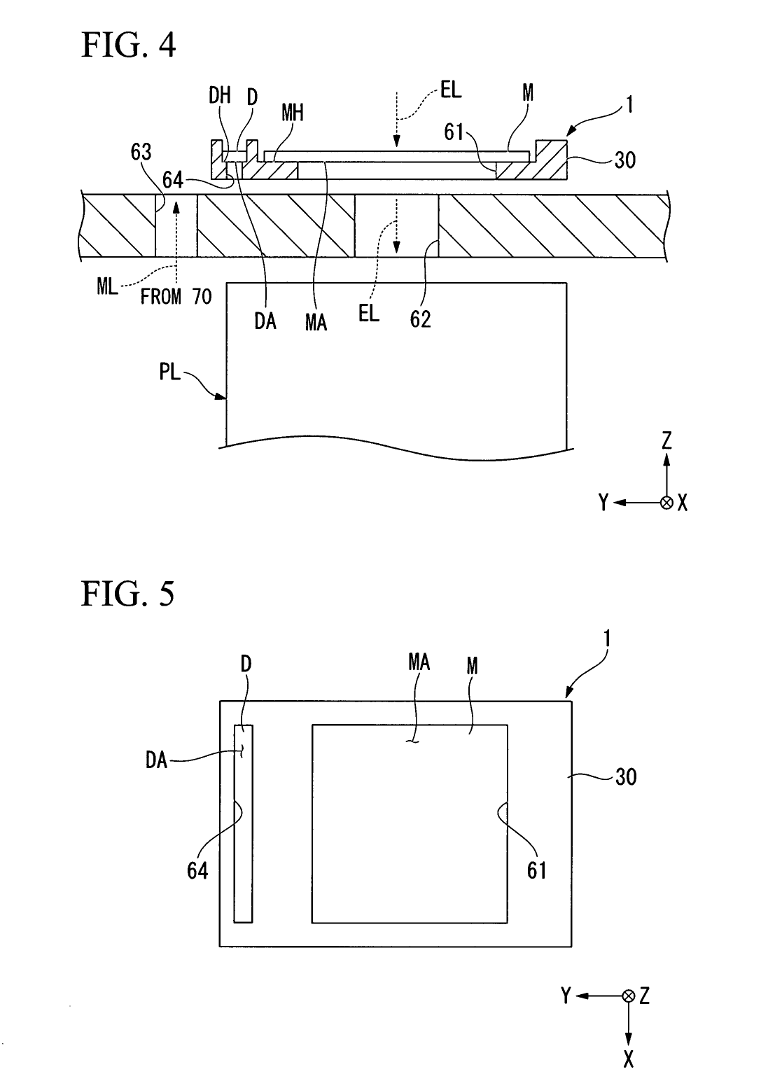

FIG. 4 is a cross section view of the side showing the neighborhood of the mask stage 1 schematically. FIG. 5 is a schematic plan view of the mask stage 1 viewed from the bottom (−Z side). As shown in FIG. 4 and FIG. 5, the mask stage 1 has a first opening 61 and a fourth opening 64. The first opening 61 and the fourth opening 64 are formed side by side in the Y-axis direction. The mask stage base 6 has a second opening 62 and a third opening 63. The second opening 62 and the third opening 63 are formed side by side in the Y-axis direction.

In FIG. 4, the mask stage 1 has a first holding mechanism MH to hold the mask M and a second holding mechanism DH to hold the reference member D. The first holding mechanism MH and the second holding mechanism DH are formed side by side in the Y-axis direction.

The first holding mechanism MH holds a part of the area wherein no pattern is formed from the pattern-formed surface MA on which the pattern of mask M is formed. The second holding mechanism DH holds a part of the area wherein no pattern is formed, from the reference surface DA of the reference member D. The first holding mechanism MH of the mask stage 1 holds the mask M such that the pattern-formed area of the mask M is disposed in the first opening 61. The second holding mechanism DH of the mask stage 1 holds the reference member D such that the reference surface DA of the reference member D is disposed in the fourth opening 64.

The first holding mechanism MH of the mask stage 1 in the present embodiment the mask M such that the pattern-formed surface MA of the mask M is substantially parallel to the XY plane. The second holding mechanism DH of the mask stage 1 holds the reference member D such that the reference surface DA of the reference member D is substantially parallel to the XY plane.

The illumination system IL of the present embodiment illuminates the exposure light EL from above the mask stage 1 toward the mask stage 1 (mask M). The exposure light EL from the illumination system IL passes through the mask M and the first opening 61 of the mask stage 1, and then passes through the second opening 62 of the mask stage base 6. The detection apparatus 70 of the present embodiment directs the detection light ML from below the mask stage base 6 toward the mask stage base 6. The detection light ML from the detection apparatus 70 passes through the third opening 63 of the mask stage base 6, and then passes through either the first opening 61 or the fourth opening 64 of the mask stage 1.

The second opening 62 is formed on the light path of the exposure light EL. During the exposure of the substrate P, the control apparatus 3 drives the mask stage drive device 1D in the Y-axis direction using the mask stage 1 so that the first opening 61 of the mask stage 1 is disposed above the light path of the exposure light EL, and thereby adjusts the position of the mask stage 1 on the mask stage base 6. During the exposure of the substrate P, the exposure light EL passes through the first opening 61 of the mask stage 1 and the second opening 62 of the mask stage base 6.

The third opening 63 is formed on the light path of the detection light ML. During the detecting operation of the surface positional information of the pattern-formed surface MA of the mask M using the detection apparatus 70, the control apparatus 3 drives the mask stage 1 in the Y-axis direction using the mask stage drive device 1D such that the first opening 61 of the mask stage 1 is disposed above the light path of the detection light ML, and thereby adjusts the position of the mask stage 1 on the mask stage base 6. During the detecting operation of the surface positional information of the pattern-formed surface MA of the mask M held in the mask stage 1, the detection apparatus 70 directs the detection light ML on the pattern-formed surface MA of the mask M, through the third opening 63 of the mask stage base 6 and the first opening 61 of the mask stage 1.

Also, during the detecting operation of the surface positional information of the reference surface DA of the reference member D using the detection apparatus 70, the control apparatus 3 drives the mask stage 1 in the Y-axis direction using the mask stage drive device 1D such that the fourth opening 64 of the mask stage 1 is disposed above the light path of the detection light ML, and thereby adjusts the position of the mask stage 1 on the mask stage base 6. During the detecting operation of the surface positional information of the reference surface DA of the reference member D of the mask stage 1, the detection apparatus 70 directs the detection light ML on the reference surface DA of the reference member D, through the third opening 63 of the mask stage base 6 and the fourth opening 64 of the mask stage 1.

In this way, in the present embodiment, the exposure light EL as well as the detection light ML can pass through the first opening 61. The exposure light EL can be passed through the second opening 62. The detection light ML can be passed through the third opening 63. The detection light ML can be passed through the fourth opening 64. The detection apparatus 70 directs the detection light ML on the pattern-formed surface MA of the mask M held in the mask stage 1 through the first opening 61 formed in the mask stage 1, and can detect the surface positional information of the pattern-formed surface MA based on the reception results of the detection light ML through the pattern-formed surface MA. Also, the detection apparatus 70 directs the detection light ML on the reference surface DA of the reference member D, and can detect the surface positional information of the reference surface DA, based on the reception results of the detection light ML through the reference surface DA.

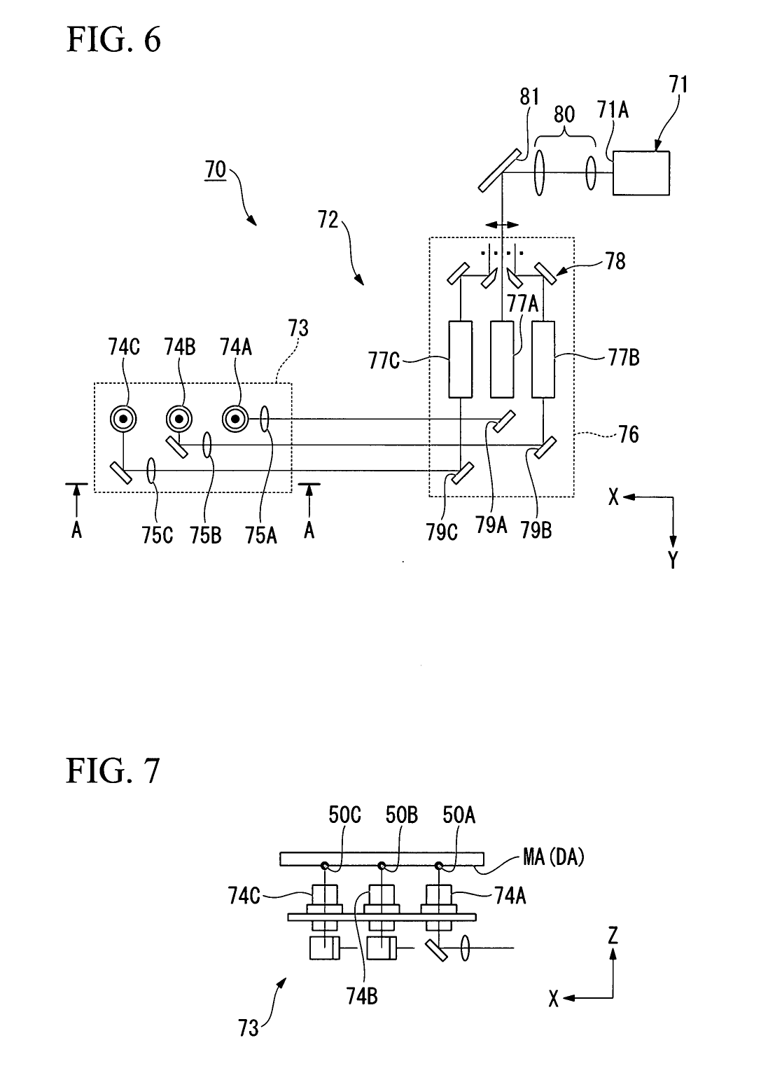

FIG. 6 is a schematic configuration showing the detection apparatus 70.

FIG. 7 is a side view showing the substantial parts of the detection apparatus 70, and is equivalent to the view from the line A-A in FIG. 6. As mentioned above, the detection apparatus 70 can direct the detection light ML on either the pattern-formed surface MA of the mask M or the reference surface DA of the reference member D. However, in the description below, the example of the detection apparatus 70 directing the detection light ML on the pattern-formed surface MA of the mask M is given.

The detection apparatus 70 can optically detect the surface positional information of the pattern-formed surface MA of the mask M, can project the detection light ML on the pattern-formed surface MA of the mask M, and is provided with a sensor unit 71 that can receive the detection light ML reflected from the pattern-formed surface MA, and an optical unit 72 through which the detection light ML passes.

The sensor unit 71 includes a light source apparatus that emits the detection light ML, and a reception element that receives light from the detection light ML. In the present embodiment, the sensor unit 71 can emit laser beam with light beam of diameter approximately 2 μm and a wavelength of approximately 670 nm, for example, as the detection light ML, and is provided with an emitting surface 71A that emits the detection light ML.

The optical unit 72 is provided with a plurality of optical elements. It can guide the detection light ML emitted by the sensor unit 71 including the light source apparatus to the pattern-formed surface MA of the mask M, and can also guide the detection light ML reflected from the pattern-formed surface MA of the mask M to the sensor unit 71 including the reception element.

The detection apparatus 70 directs the detection light ML on the pattern-formed surface MA of the mask M held in the mask stage 1 through the optical unit 72, the third opening 63 and the first opening 61, and receives the detection light ML reflected from the pattern-formed surface MA with the reception element of the sensor unit 71, through the optical unit 72. The detection apparatus 70 detects the surface positional information of the pattern-formed surface MA based on the reception result of the sensor unit 71 (reception element). In the present embodiment, the detection apparatus 70 is provided with laser confocal optics. The laser confocal optics is provided with pinhole disposed at the imaging position (in front of the reception element), and can remove light from positions other than the focusing position of the optical system. In the laser confocal optics, the amount of light received by the reception element at the focusing position is adequately large, so the position of the surface to be detected (pattern-formed surface MA) for the focusing position can be satisfactorily detected.

In the present embodiment, the sensor unit 71 has a drivable optical system (not illustrated), and by driving this optical system, the positional relationship between the position of the surface to be detected (pattern-formed surface MA) and the focusing position can be adjusted. Accordingly, the detection apparatus 70 can direct the reflected detection light ML on each of a plurality of detection points of the pattern-formed surface MA and receive the same with the reception element through the pinhole. Moreover, the sensor unit 71 detects the surface positional information corresponding to the specified reference position (origin). The detection apparatus 70 can satisfactorily detect the position of the surface to be detected (pattern-formed surface MA) corresponding to the reference position (origin) based on the amount of light received in the reception element and the shift value of the optical system. In the present embodiment, the detection apparatus 70 can satisfactorily detect the directed position in the Z-axis direction on which the detection light ML has been directed on (detection point) from the pattern-formed surface MA of the mask M.

In the present embodiment, the control apparatus 3 sets a plurality of areas on the pattern-formed surface MA of the mask M, and detects the surface positional information of each of the plurality of areas using the detection apparatus 70. The control apparatus 3 uses the detection apparatus 70 to directs the detection light ML on each of the areas 50A, 50B, 50C of the pattern-formed surface MA of the mask M to detects the surface positional information. The first, second, and third areas 50A, 50B and 50C are set side by side in the X-axis direction in the present embodiment. The detection apparatus 70 emits the detection light ML from the emitting surface 71A of the sensor unit 71, and directs the detection light ML on the areas 50A, 50B, and 50C of the pattern-formed surface MA of the mask M held in the mask stage 1 through the optical unit 72, the third opening 63, and the first opening 61, and receives the detection light ML reflected from the pattern-formed surface MA through the optical unit 72 with the sensor unit 71, and detects the surface positional information of each of the areas 50A, 50B and 50C, based on the reception results.

In the present embodiment, the sensor unit 71 unit including the light source apparatus that emits the detection light ML is one unit. The optical unit 72 guides the detection light ML emitted by the sensor unit 71 to one of the areas to be detected among the plurality of areas 50A, 50B, 50C set in the pattern-formed area of the mask M.

The optical unit 72 of the detection apparatus 70 is provided with a first optical unit 73 and a second optical unit 76. The first optical unit 73 has a plurality (three) of first objective lenses 74A, 74B, 74C and input lenses 75A, 75B and 75C installed to correspond to the plurality of multiple areas (three areas) 50A, 50B and 50C respectively, set in the pattern-formed surface MA of the mask M. The second optical unit 76 guides the detection light ML emitted from the specified position of the emitting surface 71A of the sensor unit 71 to the first objective lens (input lens) corresponding to the area to be detected from among plurality of first objective lenses 74A, 74B, 74C (input lenses 75A, 75B, 75C) of the first optical unit 73.

The second optical unit 76 is provided with: a plurality (3) second objective lenses 77A, 77B, 77C, installed to correspond to a plurality of first objective lenses 74A, 74B, 74C and by extension, to a plurality of areas 50A, 50B, 50C; an optical system 78 for setting the directing position of the detection light ML emitted by the emitting surface 71A of the sensor unit 71 incident on the second objective lens corresponding to the area to be detected from among a plurality of second objective lenses 77A, 77B, 77C; and reflecting mirrors 79A, 79B, 79C for guiding the detection light ML passing through each of the second objective lenses 77A, 77B, 77C and installed so as to correspond to the second objective lenses 77A, 77B, 77C, to a plurality of first objective lenses 74A, 74B, 74C (input lenses 75A, 75B, 75C) of the first optical unit 73. The optical system 78 for setting the directing position is installed at an optically conjugated position with the pattern-formed surface MA of the mask M. The optical system 78 for setting the directing position sets the directed position of the detection light ML in the pattern-formed surface MA such that the detection light ML emitted from the specified position of the emitting surface 71A of the sensor unit 71 is directed on the area to be detected from among a plurality of areas 50A, 50B, 50C set in the pattern-formed surface MA. The optical system 78 for setting the directing position sets the directing position of the detection light ML in the pattern-formed surface MA by making the detection light ML emitted from the specified position of the emitting surface 71A of the sensor unit 71 incident on the second objective lens corresponding to the area of the pattern-formed surface MA to be detected from among a plurality of second objective lenses 77A, 77B, 77C.

The detection apparatus 70 makes the detection light ML emitted from the specified position of the emitting surface 71A of the sensor unit 71 incident on the optical system 78 for setting the directing position of the second optical unit 76, through the beam expander optical system 80 and the reflecting mirror 81. The detection apparatus 70 directs the detection light ML emitted from the specified position of the emitting surface 71A of the sensor unit 71 on the detection point within the area to be detected in the pattern-formed surface MA, through the first objective lens corresponding to the second objective lens using the optical system 78 for setting the directing position by making the detection light incident on the second objective lens corresponding to the area to be detected in the pattern-formed surface MA from the plurality of second objective lenses 77A, 77B, and 77C.

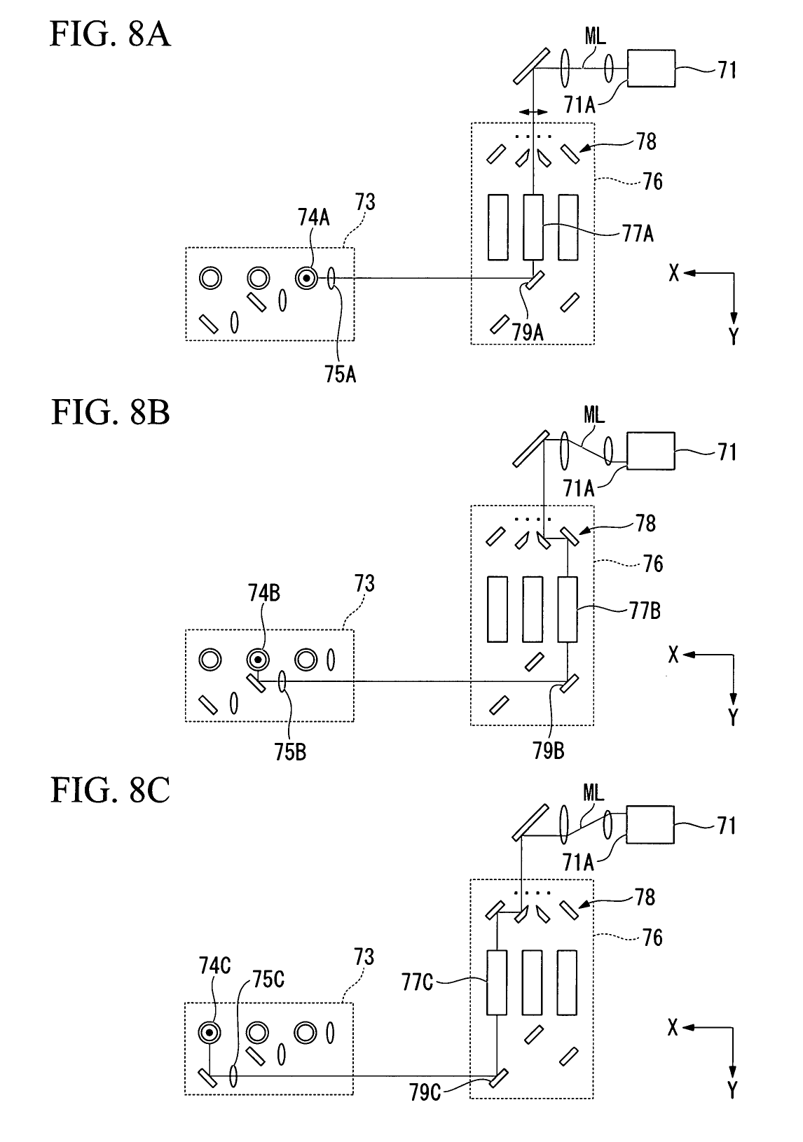

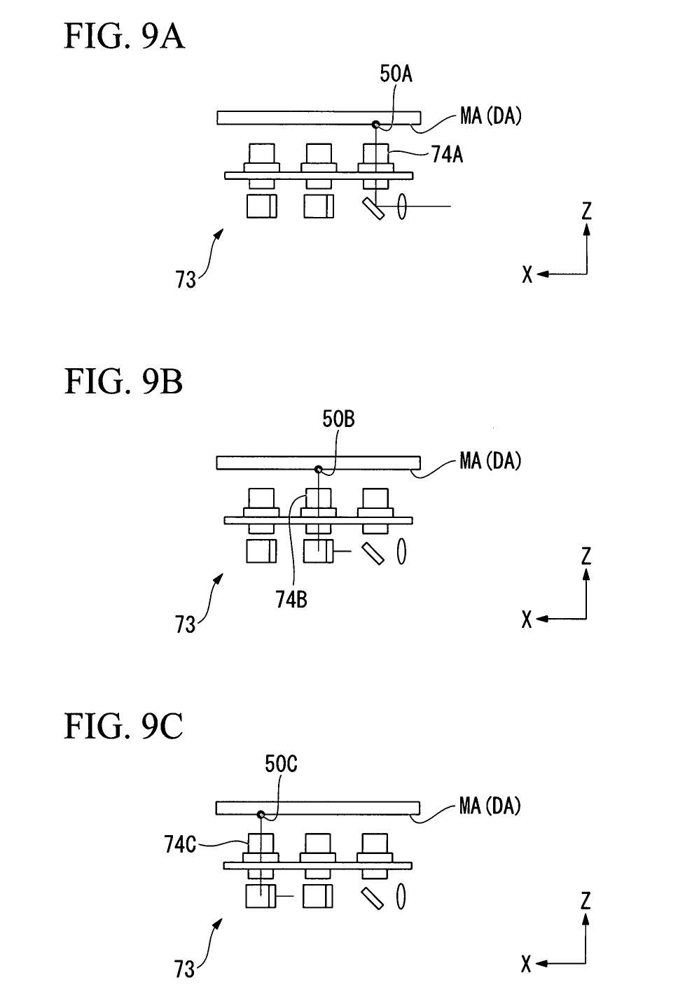

FIG. 8A, FIG. 8B, and FIG. 8C show the state of the detection light ML that the detection apparatus 70 directs on the specified detection point in each of the areas 50A, 50B and 50C respectively, of the pattern-formed surface MA. FIG. 8A shows the state of the detection light ML directed on the specified detection point in the first area 50A. FIG. 8B shows the state of the detection light ML directed on the specified detection point in the second area 50B. FIG. 8C shows the state of the detection light ML directed on the specified detection point in the third area 50C. FIG. 9A shows the side view of the substantial parts of FIG. 8A; FIG. 9B shows the side view of the substantial parts of FIG. 8B; and FIG. 9C shows the side view of the substantial parts of FIG. 8C.

In the present embodiment, the detection apparatus 70 changes the position of the detection light ML emitted from the emitting surface 71A of the sensor unit 71 so as to direct the detection light ML on the area to be detected among the plurality of areas 50A, 50B and 50C of the pattern-formed surface MA. The detection apparatus 70 changes the position of incidence of the detection light ML corresponding to the optical system 78 for setting the directing position by changing the emitting position of the detection light ML from the emitting surface 71A of the sensor unit 71. The optical system 78 for setting the directing position can change the emitting position of the detection light ML corresponding to the position of incidence of the detection light ML from the sensor unit 71. It can make the detection light ML incident on the second objective lens corresponding to the area to be detected from among a plurality of second objective lenses 77A, 77B, 77C.

In the present embodiment, the detection apparatus 70 can change the directing position of the detection light ML in the pattern-formed surface MA in the X-axis direction by changing the Y-axis direction (in the figure) of the emitting position of the detection light ML in the emitting surface 71A of the sensor unit 71.

In this way, the detection apparatus 70 in the present embodiment can direct the detection light ML on each of the plurality of positions (three positions) that differ from each other in the X-axis direction in the pattern-formed surface MA of the mask M, and can detect the positional information of each of the directed positions (detection points) in the Z-axis direction. The detection apparatus 70 is provided with a plurality of optical systems including first objective lenses 74A, 74B, 74C; input lenses 75A, 75B, 75C; reflecting mirrors 79A, 79B, 79C; and second objective lenses 77A, 77B, 77C corresponding to the plurality of areas 50A, 50B, 50C respectively, and it directs the detection light ML in the pattern-formed surface MA through the optical system corresponding to the area to be detected among the plurality of these optical systems.

Moreover, the detection apparatus 70 of the present embodiment detects the surface positional information (position of the detection point in the Z-axis direction) of the pattern-formed surface MA while moving slightly the directing position of the detection light ML in a direction inclined to the Y-axis direction in the pattern-formed surface MA.

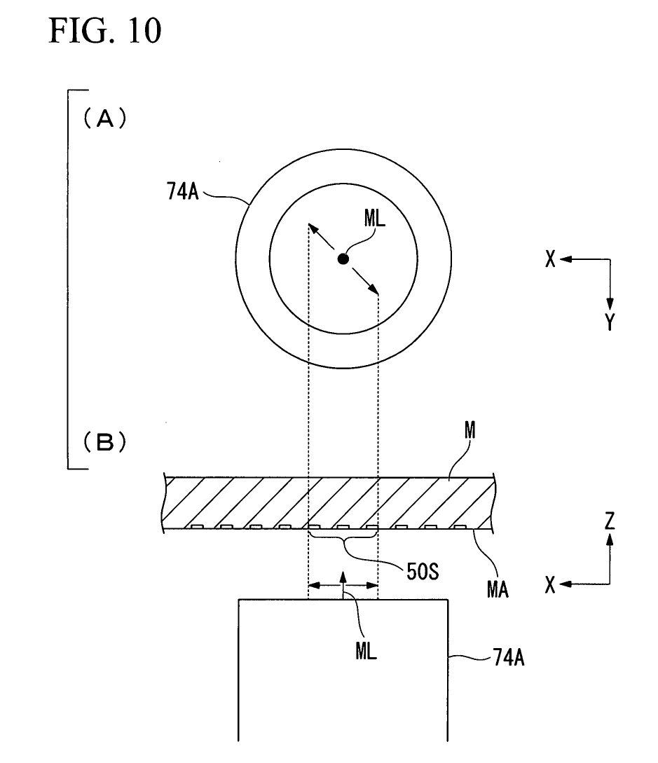

FIG. 10 is a schematic showing the state of the detection light ML directed on the specified detection point in the first area 50A of the pattern-formed surface MA. The part (A) in FIG. 10 shows the schematic of the first objective lens 74A viewed from above; while the part (B) in FIG. 10 shows the side cross section of the first objective lens 74A. As shown in FIG. 10, the detection apparatus 70 detects the surface positional information of the pattern-formed surface MA while slightly moving the directing position of the detection light ML at an inclination to the Y-axis direction in the pattern-formed surface MA (in the XY plane). That is, the detection apparatus 70 slightly moves the detection light ML at an inclination with the Y-axis direction in a very small area 50S including the detection point of the pattern-formed surface MA, and detects the surface positional information (at the position of the detection point in the Z-axis direction), based on the reception results of the detection light ML directed on the very small area 50S. For example, the detection apparatus 70 slightly moves the detection light ML in a direction inclined at an angle of 45 degrees with the Y-axis direction in the very small area 50S in the pattern-formed surface MA, such that it reciprocates with a stroke of about ±80 μm, for instance, taking the specified point (detection point) as the reference. The detection apparatus 70 determines the mean value of the position in the Z-axis direction in a very small area 50S of the pattern-formed surface MA, based on the reception results of the detection light ML.

The mask M of the present embodiment has a specified pattern formed on it using a photo shielding film of chrome or the like in a transparent plate member such as a glass plate. Parts with pattern (parts in which photo shielding film exists) and parts with no pattern (parts in which photo shielding film does not exist) are mixed with each other in the pattern-formed surface MA. The reflectivity to the detection light ML varies in the parts with pattern compared to the parts with no pattern. For this reason, the position in the Z-axis direction of the detection point guided based on the reception results of the detection light ML directed on the detection point of the part with pattern may differ from the position in the Z-axis direction of the detection point guided based on the reception results of the detection light ML directed on the detection point of the part with no pattern. The very small area 50S is set such that both parts with pattern and parts with no pattern are included in this area. By determining the mean value of the position in the Z-axis direction of this very small area 50S, the positional information of the pattern-formed surface MA (position in the Z-axis direction of the detection point in the very small area 50S) can be determined with good precision. That is, in the present embodiment, the detection apparatus 70 takes the mean value of the position of the very small area 50S in the Z-axis direction as the position of the detection point in that very small area 50S in the Z-axis direction.

If a line pattern (line and space pattern) formed along the Y-axis direction (or the X-axis direction) for example, is the main component of the pattern formed in the pattern-formed surface MA, the directed position of the detection light ML in the pattern-formed surface MA may be moved slightly in an inclined direction with respect to the Y-axis direction (or the X-axis direction), and the mean value of the position in the Z-axis direction of the very small area 50S may be determined based on the reception results of the detection light ML, the effect of the line pattern can be suppressed, and the positional information of the pattern-formed surface MA (at the position of the detection point in the very small area 50S in the Z-axis direction) can be determined with good precision.

Here, the example of fine motion of the detection light ML emitted to the pattern-formed surface MA from the first objective lens 74A has been described, but the detection apparatus 70 can also slightly move the detection light ML emitted to the pattern-formed surface MA from the second and third objective lenses 74B, 74C.

The detection of surface positional information of the pattern-formed surface MA of the mask M was taken up as an example and described above. The detection apparatus 70 directs the detection light ML emitted from the sensor unit 71 on the reference surface DA of the reference member D through the optical unit 72, the third opening 63, and the fourth opening 64. The detection light ML reflected from the reference surface DA through the optical unit 72 is received by the sensor unit 71, and the surface positional information of the reference surface DA can be detected based on the reception results. Also, the control apparatus 3 can set a plurality of areas on the reference surface DA of the reference member D corresponding to the plurality of areas 50A, 50B, 50C set on the pattern-formed surface MA of the mask M, and using the detection apparatus 70, it can direct the detection light ML on each area of the reference surface DA of the reference member D and can detect the surface positional information.

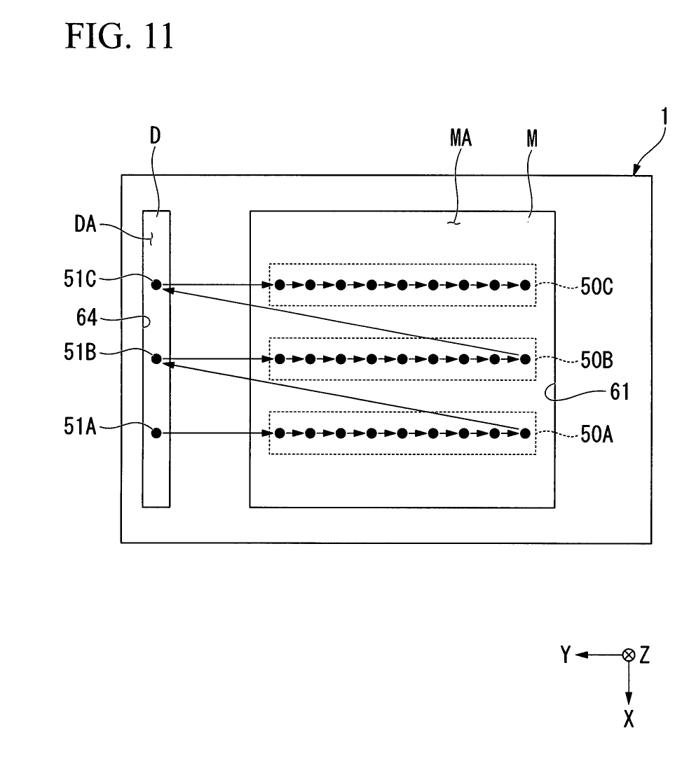

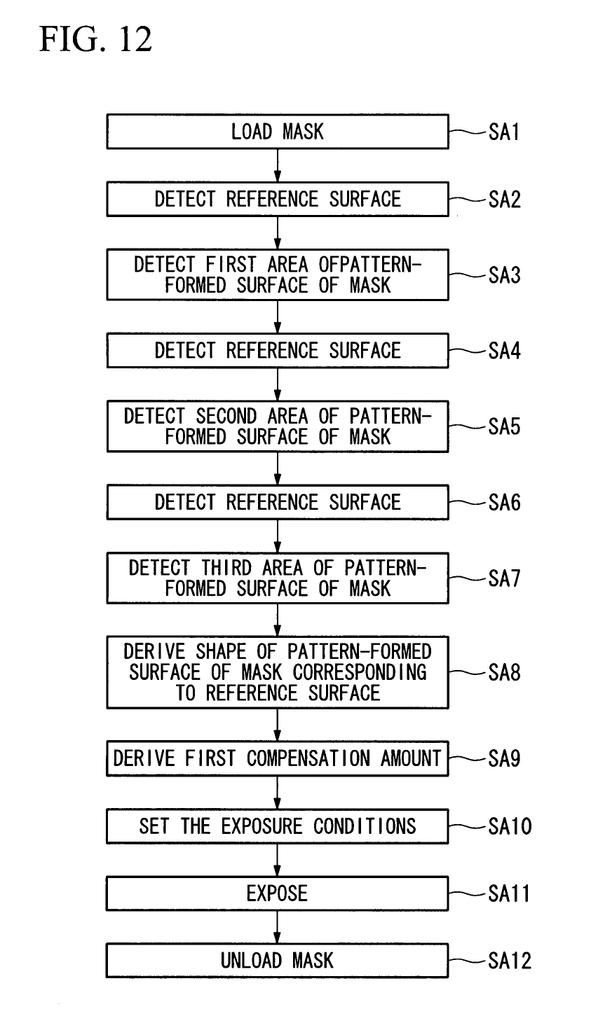

Next, an embodiment of the method to expose substrate P using the exposure apparatus EX having the configuration mentioned above is described referring to the schematic of FIG. 11 and the flow chart of FIG. 12. In the present embodiment, the control apparatus 3 sets the first, second, and third areas 50A, 50B and 50C on the pattern-formed surface MA of the mask M, and detects the surface positional information of each of the plurality of the areas 50A, 50B, 50C using the detection apparatus 70. As shown in FIG. 11, the first, second and third areas 50A, 50B and 50C, are areas that extend in the Y-axis direction and are set side by side in the X-axis direction. A plurality of detection points are set in each of the areas 50A, 50B and 50C along the Y-axis direction. The control apparatus 3 uses the detection apparatus 70 to direct the detection light ML on each of the plurality of detection points of the areas 50A, 50B and 50C, and acquires the surface positional information of each of the areas 50A, 50B and 50C (form, flatness map data).

First, the control apparatus 3 loads (transports in) the mask M on the mask stage 1 using the specified transportation system (step SA1). The mask stage 1 holds the loaded mask M.

Next, the control apparatus 3 starts the action of detecting the positional information of the reference surface DA of the reference member D installed in the mask stage 1 (step SA2), using the detection apparatus 70.

When detecting the surface positional information of the reference surface DA, the control apparatus 3, while measuring the positional information of the mask stage 1 using the laser interferometer 13, drives the mask stage 1 in the Y-axis direction using the mask stage drive device 1D such that the fourth opening 64 of the mask stage 1 is disposed on the light path of the detection light ML, and adjusts the position of the mask stage 1 on the mask stage base 6.

In the present embodiment, the control apparatus 3 firstly adjusts the emitting position of the detection light ML in the emitting surface 71A of the detection apparatus 70 such that detection light ML is directed on the detection point in the fourth area 51A corresponding to the first area 50A of the pattern-formed surface MA from the reference surface DA. That is, the control apparatus 3 sets the state of the detection apparatus 70 to the state shown in FIG. 8A. The control apparatus 3 directs the detection light ML on the reference surface DA of the reference member D through the third opening 63 of the mask stage base 6, and the fourth opening 64 of the mask stage 1. The detection light ML emitted from the specified position of emitting surface 71A of the sensor unit 71 is directed substantially vertically on the detection point in the fourth area 51A of the reference surface DA, through the optical unit 72, the third opening 63, and the fourth opening 64. The detection light ML reflected by the reference surface DA is received by the sensor unit 71 through the fourth opening 64, the third opening 63 and the optical unit 72. The detection apparatus 70 determines the positional information of the detection point in the fourth area 51A of the reference surface DA in the Z-axis direction, based on the reception results of the sensor unit 71. The control apparatus 3 stores the positional information of the fourth area 51A (detection point in the fourth area 51A) of the determined reference surface DA in the Z-axis direction as first reference position (first origin) in the storage apparatus 4.

Moreover, the control apparatus 3 sets the position of the fourth area 51A in the Z-axis direction, that is, the first reference position (first origin) as the reference position (origin) of the sensor unit 71. That is, the reference position (origin) of the sensor unit 71 is reset to the first reference position (first origin). The control apparatus 3 resets the reference position (origin) of the sensor unit 71 using the positional information of the fourth area 51A (detection point in the fourth area 51A) of the reference surface DA in the Z-axis direction.

Next, the control apparatus 3 starts the action of detecting the positional information of the first area 50A of the pattern-formed surface MA of the mask M held in the mask stage 1 using the detection apparatus 70 (step SA3).

When detecting the surface positional information of the pattern-formed surface MA, the control apparatus 3, while measuring the positional information of the mask stage 1 using the laser interferometer 13, drives the mask stage 1 in the Y-axis direction using the mask stage drive device 1D such that the first opening 61 of the mask stage 1 is disposed on the light path of the detection light ML, and adjusts the position of the mask stage 1 on the mask stage base 6.

Also, the control apparatus 3 adjusts the emitting position of the detection light ML in the emitting surface 71A of the detection apparatus 70 such that the detection light ML is directed on the specified detection point in the first area 50A of the pattern-formed surface MA.

The control apparatus 3 directs the detection light ML on the specified detection point in the first area 50A of the pattern-formed surface MA of the mask M, through the third opening 63 of the mask stage base 6 and the first opening 61 of the mask stage 1. The detection light ML emitted from the specified position of the emitting surface 71A of the sensor unit 71 is directed substantially vertically on the pattern-formed surface MA, through the optical unit 72, the third opening 63, and the first opening 61. The detection light ML reflected by the pattern-formed surface MA, is received by the sensor unit 71 through the first opening 61, the third opening 63 and the optical unit 72. The detection apparatus 70 determines the positional information of the specified detection point in the first area 50A of the pattern-formed surface MA in the Z-axis direction, based on the reception results of the sensor unit 71.

The control apparatus 3 directs the detection light ML sequentially on each of the plurality of detection points set in the first area 50A of the pattern-formed surface MA, through the third opening 63 and the first opening 61, while performing stepping movement of the mask stage 1 in the Y-axis direction in the specified area including the third opening 63 on the mask stage base 6. The control apparatus 3 can obtain the positional information of each detection point in the Z-axis direction by directing the detection light ML sequentially on each of the plurality of detection points set in the first area 50A of the pattern-formed surface MA in the Y-axis direction, while moving the mask stage 1 (mask M) in the Y-axis direction.

The control apparatus 3 can determine the surface positional information of the first area 50A, based on the positional information of the plurality of detection points in the Z-axis direction in the first area 50A of the pattern-formed surface MA. Moreover, in step SA2, the positional information of the fourth area 51A of the reference surface DA in the Z-axis direction is set as the first reference position (first origin), and the control apparatus 3 derives the surface positional information of the first area 50A corresponding to the first reference position.

After the operation of detecting the surface positional information of the first area 50A of the pattern-formed surface MA is completed, the control apparatus 3 starts the operation of detecting the positional information of the reference surface DA of the reference member D installed in the mask stage 1, using the detection apparatus 70 (step SA4).

The control apparatus 3 controls the detection apparatus 70 and the mask stage 1 such that the detection light ML is directed on the detection point in the fifth area 51B corresponding to the second area 50B of the pattern-formed surface MA from the reference surface DA. That is, the control apparatus 3 moves the directing position of the detection light ML in the X-axis direction using the detection apparatus 70 by adjusting the emitting position of the detection light ML in the emitting surface 71A of the detection apparatus 70, and also, drives the mask stage 1 in the Y-axis direction using the mask stage drive device 1D such that the fourth opening 64 of the mask stage 1 is disposed above the light path of the detection light ML, while measuring the positional information of the mask stage 1 using the laser interferometer 13, and adjusts the position of the mask stage 1 on the mask stage base 6. The detection apparatus 70 is set in the state shown in FIG. 8B.

The control apparatus 3 directs the detection light ML on the reference surface DA of the reference member D through the third opening 63 of the mask stage base 6, and the fourth opening 64 of the mask stage 1. The detection light ML emitted from the specified position of the emitting surface 71A of the sensor unit 71 is directed substantially vertically on the detection point in the fifth area 51A of the reference surface DA, through the optical unit 72, the third opening 63, and the fourth opening 64.

The detection apparatus 70 determines the positional information of the detection point in the fifth area 51B of the reference surface DA in the Z-axis direction, based on the reception results by the sensor unit 71 of the detection light ML reflected by the reference surface DA. The control apparatus 3 then stores the positional information in the Z-axis direction of the fifth area 51B (detection point in the fifth area 51B) of the determined reference surface DA in the storage apparatus 4 as the second reference position (second origin).

Moreover, the control apparatus 3 sets the position of the fifth area 51B in the Z-axis direction, that is, the second reference position (second origin) as the reference position (origin) of the sensor unit 71. That is, the reference position (origin) of the sensor unit 71 is reset to the second reference position (second origin). The control apparatus 3 resets the reference position (origin) of the sensor unit 71 using the positional information of the fifth area 51B (detection point in the fifth area 51B) of the reference surface DA in the Z-axis direction.

Next, the control apparatus 3 starts the action of detecting the positional information of the second area 50B of the pattern-formed surface MA of the mask M held in the mask stage 1 using the detection apparatus 70 (step SA5).

The control apparatus 3 drives the mask stage 1 in the Y-axis direction using the mask stage drive device 1D such that the first opening 61 of the mask stage 1 is disposed above the light path of the detection light ML, while measuring the positional information of the mask stage 1 using the laser interferometer 13, and adjusts the position of the mask stage 1 on the mask stage base 6.

Also, the control apparatus 3 adjusts the emitting position of the detection light ML in the emitting surface 71A of the detection apparatus 70 such that the detection light ML is directed on the specified detection point in the second area 50B of the pattern-formed surface MA.

The control apparatus 3 directs the detection light ML on the specified detection point in the second area 50B of the pattern-formed surface MA of the mask M, through the third opening 63 of the mask stage base 6 and the first opening 61 of the mask stage 1. The detection light ML emitted from the specified position of the emitting surface 71A of the sensor unit 71 is directed substantially vertically on the pattern-formed surface MA, through the optical unit 72, the third opening 63, and the first opening 61. The detection light ML reflected by the pattern-formed surface MA, is received by the sensor unit 71 through the first opening 61, the third opening 63 and the optical unit 72. The detection apparatus 70 determines the positional information of the specified detection point in the second area 50B of the pattern-formed surface MA in the Z-axis direction, based on the reception results of the sensor unit 71.

The control apparatus 3 directs the detection light ML sequentially on each of the plurality of detection points set in the second area 50B of the pattern-formed surface MA, through the third opening 63 and the first opening 61, while performing stepping movement of the mask stage 1 in the Y-axis direction in the specified area including the third opening 63 on the mask stage base 6. The control apparatus 3 can determine the positional information of each detection point in the Z-axis direction by directing the detection light ML sequentially on each of the plurality of detection points set in the second area 50B of the pattern-formed surface MA in the Y-axis direction, while moving the mask stage 1 (mask M) in the Y-axis direction.

The control apparatus 3 can determine the surface positional information of the second area 50B, based on the positional information of the plurality of detection points in the Z-axis direction in the second area 50B of the pattern-formed surface MA. Moreover, in step SA4, the positional information of the fifth area 51B of the reference surface DA in the Z-axis direction is set as the second reference position (second origin), and the control apparatus 3 derives the surface positional information of the second area 50B corresponding to the second reference position.

After the operation of detecting the surface positional information of the second area 50B of the pattern-formed surface MA is completed, the control apparatus 3 starts the operation of detecting the positional information of the reference surface DA of the reference member D installed in the mask stage 1, using the detection apparatus 70 (step SA6).

The control apparatus 3 controls the detection apparatus 70 and the mask stage 1 such that the detection light ML is directed on the detection point in the sixth area 51C corresponding to the third area 50C of the pattern-formed surface MA from the reference surface DA. That is, the control apparatus 3 moves the directing position of the detection light ML in the X-axis direction using the detection apparatus 70 by adjusting the emitting position of the detection light ML in the emitting surface 71A of the detection apparatus 70, and also, drives the mask stage 1 in the Y-axis direction using the mask stage drive device 1D such that the fourth opening 64 of the mask stage 1 is disposed above the light path of the detection light ML, while measuring the positional information of the mask stage 1 using the laser interferometer 13, and adjusts the position of the mask stage 1 on the mask stage base 6. The detection apparatus 70 is set in the state shown in FIG. 8C.

The control apparatus 3 then directs the detection light ML on the reference surface DA of the reference member D through the third opening 63 of the mask stage base 6, and the fourth opening 64 of the mask stage 1. The detection light ML emitted from the specified position of the emitting surface 71A of the sensor unit 71 is directed substantially vertically on the detection point in the sixth area 51C of the reference surface DA, through the optical unit 72, the third opening 63, and the fourth opening 64.

The detection apparatus 70 determines the positional information of the detection point in the sixth area 51C of the reference surface DA in the Z-axis direction, based on the reception results by the sensor unit 71 of the detection light ML reflected by the reference surface DA. The control apparatus 3 stores the positional information of the sixth area 51C (detection point in the sixth area 51C) of the determined reference surface DA in the Z-axis direction as the third reference position (third origin) in the storage apparatus 4.

Moreover, the control apparatus 3 sets the position of the sixth area 51C in the Z-axis direction, that is, the third reference position (third origin) as the reference position (origin) of the sensor unit 71. That is, the reference position (origin) of the sensor unit 71 is reset to the third reference position (third origin). The control apparatus 3 resets the reference position (origin) of the sensor unit 71 using the positional information of the sixth area 51C (detection point in the sixth area 51C) of the reference surface DA in the Z-axis direction.

Next, the control apparatus 3 starts the action of detecting the positional information of the third area 50C of the pattern-formed surface MA of the mask M held in the mask stage 1 using the detection apparatus 70 (step SA7).

The control apparatus 3 drives the mask stage 1 in the Y-axis direction using the mask stage drive device 1D such that the first opening 61 of the mask stage 1 is disposed above the light path of the detection light ML, while measuring the positional information of the mask stage 1 using the laser interferometer 13, and adjusts the position of the mask stage 1 on the mask stage base 6.

Also, the control apparatus 3 adjusts the emitting position of the detection light ML in the emitting surface 71A of the detection apparatus 70 such that the detection light ML is directed on the specified detection point in the third area 50C of the pattern-formed surface MA.

The control apparatus 3 directs the detection light ML on the specified detection point in the third area 50C of the pattern-formed surface MA of the mask M, through the third opening 63 of the mask stage base 6 and the first opening 61 of the mask stage 1. The detection light ML emitted from the specified position of the emitting surface 71A of the sensor unit 71 is directed substantially vertically on the pattern-formed surface MA, through the optical unit 72, the third opening 63, and the first opening 61. The detection light ML reflected by the pattern-formed surface MA, is received by the sensor unit 71 through the first opening 61, the third opening 63 and the optical unit 72. The detection apparatus 70 determines the positional information of the specified detection point in the third area 50C of the pattern-formed surface MA in the Z-axis direction, based on the reception results of the sensor unit 71.

The control apparatus 3 directs the detection light ML sequentially on each of the plurality of detection points set in the third area 50C of the pattern-formed surface MA, through the third opening 63 and the first opening 61, while performing stepping movement of the mask stage 1 in the Y-axis direction in the specified area including the third opening 63 on the mask stage base 6. The control apparatus 3 can obtain the positional information of each detection point in the Z-axis direction by directing the detection light ML sequentially on each of the plurality of detection points set in the third area 50C of the pattern-formed surface MA in the Y-axis direction, while moving the mask stage 1 (mask M) in the Y-axis direction.

The control apparatus 3 can determine the surface positional information of the third area 50C, based on the positional information of the plurality of detection points in the Z-axis direction in the third area 50C of the pattern-formed surface MA. Moreover, in step SA6, the positional information of the sixth area 51C of the reference surface DA in the Z-axis direction is set as the third reference position (third origin), and the control apparatus 3 derives the surface positional information of the third area 50C corresponding to the third reference position.

In this way, in the present embodiment, the control apparatus 3 implements the operation of detecting the surface positional information of the reference surface DA with the detection apparatus 70 for each operation to detect the surface positional information of each of the areas 50A, 50B, 50C of the pattern-formed surface MA before implementing the operation for detecting the surface positional information of each of the areas 50A, 50B, 50C of the pattern-formed surface MA.

Next, the control apparatus 3 derives the relative surface positional information (form, flatness map data) of the pattern-formed surface MA corresponding to the reference surface DA, based on the results of detection of the positional information of the reference surface DA and the results of detection of the surface positional information of the pattern-formed surface MA (step SA8).

When calculating the surface positional information (form, flatness map data), the surface positional information of the areas 50A, 50B, 50C of the pattern-formed surface MA are unified based on the mutual positional relationship in the Z direction of the first to third reference positions (fourth to sixth areas 51A to 51C) of the reference surface DA. The mutual positional relationships in the Z direction between the first and the third reference positions are all taken as the same value when the reference surface DA is substantially flat (for example, zero). Or, after mounting the reference member D on the mask stage 1, the Z-direction position of the first to third reference position may be measured and stored, and this value may be used.

The control apparatus 3 determines the first correction value for exposure of the substrate P in the desired state using the mask M, based on the surface positional information (contour) of the pattern-formed surface MA of the mask M determined in step SA8. Next, the control apparatus 3 sets the exposure conditions based on the determined first correction value (step SA10).

Here, the exposure conditions include at least the relative distance or the relative inclination of the surface of the substrate P relative to the pattern-formed surface MA of the mask M. Moreover, the exposure conditions include the imaging characteristics of the projection optical system PL.

Depending on the surface positional information (contour) of the pattern-formed surface MA of the mask M, the position of the image plane of the projection optical system PL may change, the image plane of the projection optical system PL may incline, the form of the image plane of the projection optical system PL may change, or aberrations such as distortion may occur, and the projection state of the pattern image through the projection optical system PL, that is, the imaging characteristics of the projection optical system PL may change. If the projection state of the pattern image changes, the substrate may not be exposed satisfactorily. The control apparatus 3 in the present embodiment determines the first correction value to expose the substrate P satisfactorily based on the surface positional information (contour) of the pattern-formed surface MA, and sets the exposure conditions including the imaging characteristics of the projection optical system PL, and at least either the relative distance or the relative inclination of the surface of the substrate P relative to the pattern-formed surface MA of the mask M, based on this first correction value.

For example, if the image plane of the by the projection optical system PL is moved in the Z-axis direction according to the form of the pattern-formed surface MA of the mask M, or if the image plane is inclined, the control apparatus 3 determines the correction value of the position related to the Z axis, θX and θY directions of the surface of the substrate P when exposing the substrate P, that is, the correction value related to the relative distance and the relative inclination of the substrate with respect to the pattern-formed surface MA of the mask M, such that the positional relationship between the image plane of the projection optical system PL and the surface of the substrate P are in the desired state (such that the image plane and the surface of the substrate P coincide, or such that offset in the image plane and the surface of the substrate P is below the permissible value). Next, the control apparatus 3 sets the position of the substrate P based on the determined first correction value.

If aberrations such as distortion of the pattern image occur due to the projection optical system PL according to the form of the pattern-formed surface MA of the mask M, the control apparatus 3 determines the correction value (for example, the shift value of the optical element) by the imaging characteristics adjusting device LC such that the desired state of the imaging characteristics of the projection optical system PL (projection state of pattern image through the projection optical system PL) are obtained. The control apparatus 3 sets the imaging characteristics of the projection optical system PL based on the determined correction value.

In the present embodiment, information related to the first correction value for exposure of the substrate P in the desired state using the mask M with the specified form of the pattern-formed surface MA is already stored in the storage apparatus 4. The control apparatus 3 can determine the first correction value for exposure of the substrate P in the desired state using the mask M, based on the stored data in the storage apparatus 4 and the surface positional information (contour) of the pattern-formed surface MA of the mask M determined in step SA8.

The control apparatus 3 exposes the substrate P while adjusting the exposure conditions based on the determined first correction value (step SA11). The exposure apparatus EX according to the present embodiment is a scanning type exposure apparatus. The control apparatus 3 directs the exposure light EL on the mask M held in the mask stage 1 while moving the mask stage 1 holding the mask M and the substrate stage 2 holding the substrate P in the specified scanning direction (Y-axis direction), and projects the pattern image of the mask M on the surface of the substrate P through the projection optical system PL.

For example, the control apparatus 3 can expose the substrate P while moving it and while adjusting the moving state of the substrate stage 2 holding the substrate P such that the positional relationship between the image plane of the projection optical system PL and the surface of the substrate P is obtained in the desired state. The surface positional information of the surface of the substrate P is detected by the focus and level detection system 18. The control apparatus 3 compensates the results of detection of the surface positional information of the surface of the substrate P by the focus and level detection system 18, based on the surface positional information of the pattern-formed surface MA of the mask M, and based on this correction value, it can control the substrate stage 2 and expose the substrate P while adjusting the position of the surface of the substrate P.

Also, the control apparatus 3 can expose the substrate P while moving it and while driving the imaging characteristics adjusting device LC such that the desired state of the imaging characteristics of the projection optical system PL is obtained.

After the exposure using the mask M is completed, the control apparatus 3 unloads (transports out) the mask M of the mask stage 1, using the specified transportation system (step SA12).

Also, the control apparatus 3 can issue alarm using the reporting apparatus 17, according to the results of detection of the detection apparatus 70. For example, in step SA8, if the determined form of the pattern-formed surface MA is judged to be abnormal, the control apparatus 3 can issue an alarm using the reporting apparatus 17. More specifically, if the maximum error (for example, the maximum deformation of the pattern-formed surface MA) corresponding to the reference position of the pattern-formed surface MA does not fall in the permissible range set beforehand and if it is judges as an abnormal value, then the control apparatus 3 can issue an alarm using the reporting apparatus 17. Also, when the maximum error corresponding to the reference position of the determined pattern-formed surface MA is an abnormal value, the control apparatus 3 treats the space between the mask stage 1 and the mask M to contain foreign matter (contamination), and it can report the same with the reporting apparatus 17.

As described above, when implementing the operation to detect the surface positional information of the areas 50A, 50B, 50C, set in the pattern-formed surface MA in order to determine the surface positional information of the pattern-formed surface MA of the mask M, the operation for detecting the surface positional information of the reference surface DA has to be implemented for each operation for detecting the surface positional information of the areas 50A, 50B, 50C of the pattern-formed surface MA before the operation for detecting the surface positional information of the areas 50A, 50B, 50C of the pattern-formed surface MA, so that the surface positional information of the pattern-formed surface MA of the mask M can be acquired accurately, and the substrate P can be exposed satisfactorily.

That is, before the detecting operation of the areas 50A, 50B, 50C of the pattern-formed surface MA, the reference position (origin) of the sensor unit 71 is reset using the results of detection of the reference surface DA for each detecting operation of the areas 50A, 50B, 50C; therefore, after calibrating the zero point drift of the sensor unit 71, the detecting operation of the 50A, 50B, 50C can be implemented. Since the surface positional information of the reference surface DA is already known, the zero point drift of the sensor unit 71 can be satisfactorily calibrated. Accordingly, the surface positional information of the areas 50A, 50B, 50C can be detected with high precision.

In the present embodiment, the sensor unit 71 including the light source apparatus that emits the detection light ML is one unit, and this is advantageous considering equipment cost and space for disposing the unit. The optical unit 72 has a plurality of optical systems corresponding to each of the areas 50A, 50B, 50C respectively. The detection light ML emitted by the sensor unit 71 passes through one of the optical systems corresponding to the area to be detected from among the plurality of optical systems of the optical unit 72. Error may occur in the results of detection depending on the differences in the optical system, based on the detection light ML passing through each optical system. However, according to the present embodiment, the reference position (origin) of the sensor unit 71 is reset using the results of detection of the reference surface DA for each detecting operation of the areas 50A, 50B, 50C before the detecting operation of the areas 50A, 50B, 50C of the pattern-formed surface MA. Therefore, the deterioration in the accuracy of detection due to the differences in the optical system is inhibited, and the surface positional information of the areas 50A, 50B, 50C can be detected with high precision.

Also, according to the present embodiment, the surface positional information of the pattern-formed surface MA of the mask M held in the mask stage 1 has been detected, so the presence of deformation and/or foreign matter in the mask M held in the mask stage 1 can be detected satisfactorily. After the detecting operation of the surface positional information of the pattern-formed surface MA is completed, an immediate transition to the exposure operation is possible. Thus, the exposure conditions can be set satisfactorily based on the results of detection of the pattern-formed surface MA, and the substrate P can be exposed satisfactorily with good efficiency.

Moreover, according to the present embodiment, the mask stage 1 is configured so as to not move in the X-axis direction. However, the detection apparatus 70 can move the directing position of the detection light ML in the X-axis direction. Therefore, the control apparatus 3 can move the mask stage 1 in the Y-axis direction, and can also move the directing position of the detection light ML in the X-axis direction by using the detection apparatus 70. As a result, surface positional information in a wide range of the pattern-formed surface MA can be acquired.

Moreover, according to the embodiment described above, three areas 50A, 50B, 50C are set in the pattern-formed surface MA, but naturally, a plurality of areas of arbitrary number greater than three can also be set.

Furthermore, in the embodiment described above, the operation to detect the reference surface DA and the operation to detect sequentially a plurality of detection points set in the pattern-formed surface MA of the mask M are repetitively implemented, but the operation to detect the reference surface DA and the operation to detect one detection point of the pattern-formed surface MA of the mask M may be repetitively implemented.

### Second Embodiment

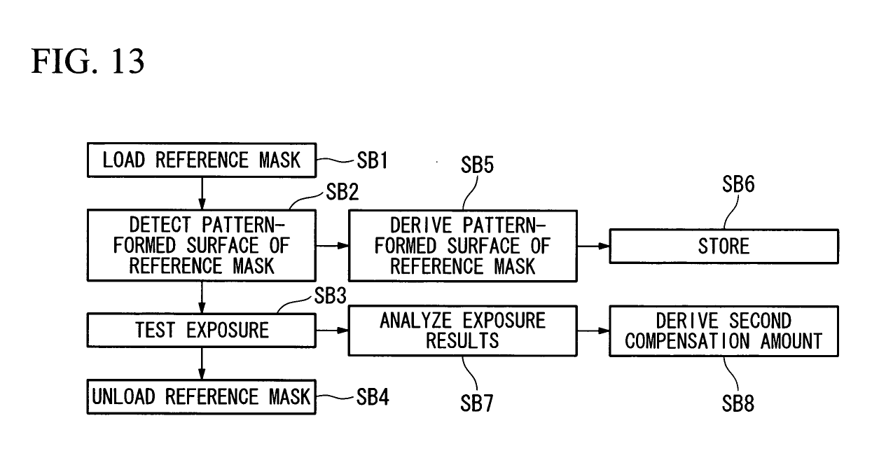

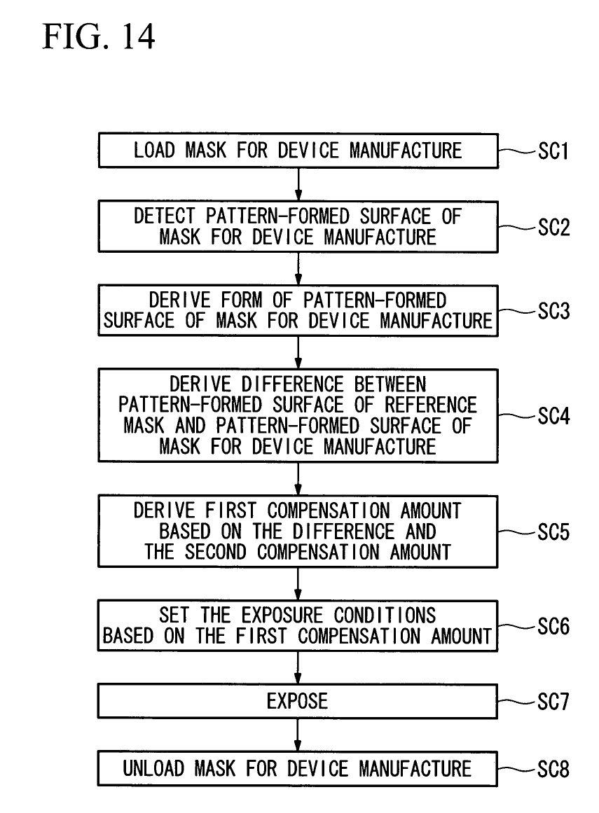

In the first embodiment described above, information related to the first correction value for exposing the substrate P in the desired state using the mask M having the pattern-formed surface MA in the specified state, was stored beforehand in the storage apparatus 4. The control apparatus 3 determines the first correction value for exposing the substrate P in the desired state using the mask M based on the stored information in the storage apparatus 4 and the surface positional information of the pattern-formed surface MA of the mask M determined using the detection apparatus 70. In the present embodiment, the sequence for determining the storage information stored in the storage apparatus 4 and one embodiment of the sequence for determining the first correction value are described referring to the flowcharts in FIG. 13 and FIG. 14.

In to the present embodiment, to determine the storage information of the storage apparatus 4, the control apparatus 3 detects the surface positional information of the pattern-formed surface MA′ of the reference mask M different from the mask M and also determines the second correction value for exposing the substrate P in the desired state using the reference mask M′ before the exposure operation using the mask M for device manufacture. The control apparatus 3 performs text exposure of the substrate P using the reference mask M′ to determine the second correction value for satisfactory exposure of the substrate P using the acquired surface positional information of the pattern-formed surface MA′ of the reference mask M′, and using the results of the test exposure, acquires the projection state of the pattern image using the reference mask M′ and associates the surface positional information of the pattern-formed surface MA′ with the projection state of the pattern image.

The reference mask M′ is loaded in the mask stage 1 (step SB1). After the reference mask M′ is loaded in the mask stage 1, the control apparatus 3 performs the operation to detect the surface positional information of the pattern-formed surface MA′ of the reference mask M′ using the detection apparatus 70, by the same procedure as in the first embodiment described above. The control apparatus 3 performs the test exposure of the substrate P using the reference mask M′ (step SB3). The reference mask M′ is unloaded after the test exposure is completed (step SB4).

The control apparatus 3 derives the surface positional information (contour) of the pattern-formed surface MA′ of the reference mask M′ based on the results of detection in step SB2 (step SB5). The control apparatus 3 stores the derived surface positional information (contour) of the pattern-formed surface MA′ of the reference mask M′ in the storage apparatus 4 (step SB6).

Moreover, the analysis of the test-exposed substrate P is carried out in the step SB3 (step SB7). For example, the pattern shape formed in the test-exposed substrate P is measured by the specified shape measurement apparatus, and these measurement results are analyzed by the control apparatus 3.

The control apparatus 3 determines the second correction value for exposure of the substrate P in the desired state using the reference mask M′, based on the results of the analysis (step SB8). The second correction value is stored in the storage apparatus 4.

For example, the control apparatus 3 determines the correction value (correction value corresponding to the results of detection by the focus and level detection system 18, correction value related to the movement conditions of the substrate stage 2) related to at least either the relative distance or the relative inclination of the surface of the substrate P for the pattern-formed surface MA′ of the reference mask M′ for exposing the substrate P in the desired state using the reference mask M′ having the pattern-formed surface MA′ in the specified shape.

Or, the control apparatus 3 determines the correction value (correction value due to the imaging characteristics adjusting device LC) related to the imaging characteristics of the projection optical system PL for exposing the substrate P in the desired state using the reference mask M′ having the pattern-formed surface MA′ in the specified shape, based on the results of analysis.

After determining the second correction value, the control apparatus 3 performs the exposure for manufacturing the device using the mask M for device manufacture.

The mask M for device manufacture is loaded in the mask stage 1 (step SC1). After the mask M is loaded in the mask stage 1, the control apparatus 3 performs the detecting operation to detect the surface positional information of the pattern-formed surface MA of the mask M using the detection apparatus 70, by the same procedure as in the first embodiment described above. The control apparatus 3 derives the surface positional information (contour) of the pattern-formed surface MA of the mask M based on the results of detection in (step SC3).

The control apparatus 3 derives the difference between the form (surface position) of the pattern-formed surface MA′ of the reference mask M′ stored in the storage apparatus 4 derived in step SB5, and the form (surface position) of the pattern-formed surface MA of the mask M derived in step SC3 (step SC4).

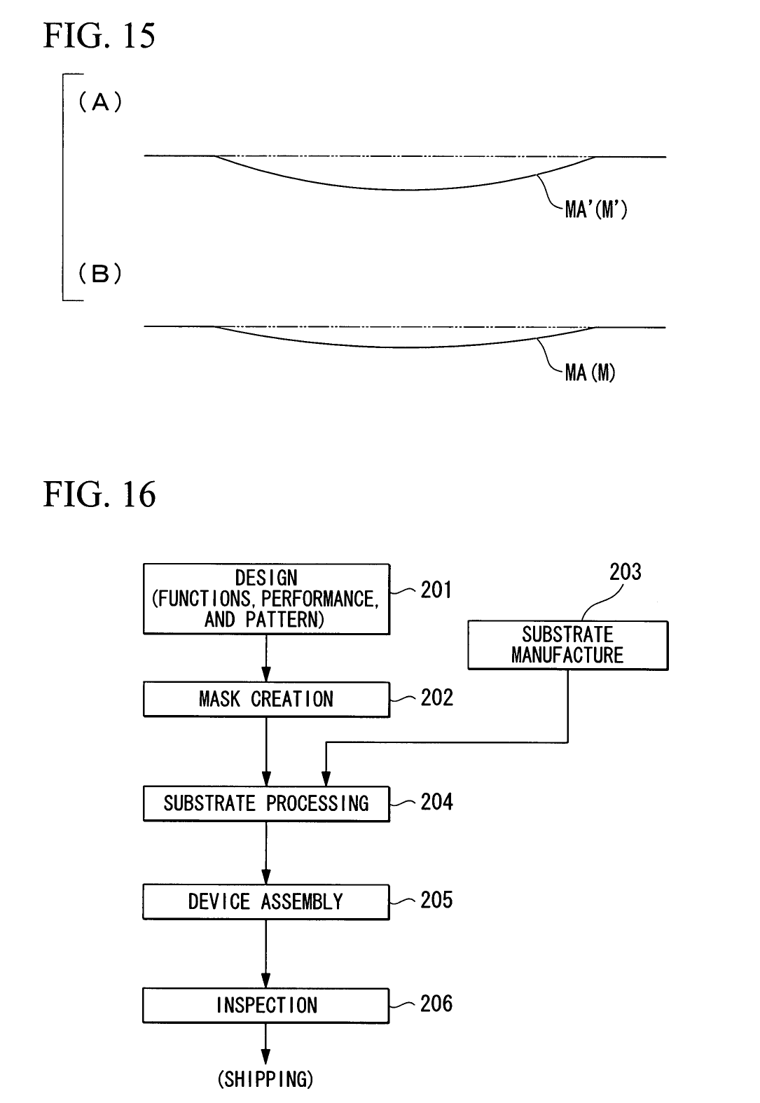

The part (A) in FIG. 15 shows the schematic of the pattern-formed surface MA′ of the reference mask M′, while the part (B) of FIG. 15 shows the schematic of the pattern-formed surface MA of the mask M for device manufacture. The reference mask M′ and the mask M for device manufacture are different masks; for example, the reference mask M′ and the mask M for device manufacture may have unique shapes or their deformation amount may differ according to the difference in thickness. That is, as shown in FIG. 15, there may be a difference in the surface position corresponding to the reference position of the pattern-formed surface MA′ of the reference mask M′ and the surface position corresponding to the reference position of the pattern-formed surface MA of the mask M for device manufacture.

After determining the difference between the surface position of the pattern-formed surface MA′ of the reference mask M′ and the pattern-formed surface MA of the mask M, the control apparatus 3 determines the first correction value for exposing the substrate P in the desired state using the mask M for device manufacture based on the determined difference and the second correction value derived in step SB8 and stored in the storage apparatus 4 (step SC5).

In the storage apparatus 4, information related to the first correction value corresponding to the second correction value is stored beforehand according to the difference between the surface position of the pattern-formed surface MA of the mask M for device manufacture and the surface position of the pattern-formed surface MA′ of the reference mask M′. Information related to the first correction value corresponding to the second correction value according to the difference between the surface position of the pattern-formed surface MA of the mask M for device manufacture and the surface position of the pattern-formed surface MA′ of the reference mask M′, can be determined beforehand, for instance, by tests or by simulation, and can be stored in the storage apparatus 4 as map data, for example.

Also, the information related to the first correction value corresponding to the second correction value according to the difference between the surface position of the pattern-formed surface MA of the mask M for device manufacture and the surface position of the pattern-formed surface MA′ of the reference mask M′, can be determined by arithmetic formulae. For example, if the image plane position of the pattern image due to the projection optical system PL varies proportionately according to the difference between surface position of the pattern-formed surface MA′ of the reference mask M and the surface position of the pattern-formed surface MA of the mask M for device manufacture, and the correction value for exposing the substrate P in the desired state using the mask M for device manufacture also varies proportionately according to the difference between surface position of the pattern-formed surface MA′ of the reference mask M and the surface position of the pattern-formed surface MA of the mask M for device manufacture, then the information can be determined by arithmetic formulae.

For instance, assume that the position corresponding to the reference position of the pattern-formed surface MA′ of the reference mask M′ is Z₀, and the second correction value for exposing the substrate P in the desired state using the reference mask M′ is R₀. When the first correction value R₁ for exposing the substrate P in the desired state using the mask M varies proportionately according to the position (that is difference) Z₁ of the pattern-formed surface MA of the mask M for device manufacture compared to the position Z₀ of the pattern-formed surface MA′ of the reference mask M′, then the relationship can be expressed by: R₁=R₀+α×Z₁ (where α is a specific constant).

The control apparatus 3 sets the exposure conditions based on the determined first correction value (step SC6). The substrate P is exposed based on the set exposure conditions (step SC7). For example, if the position of the image plane varies due to the projection optical system PL according to the surface position of the pattern-formed surface MA of the mask M, the control apparatus 3 can expose the substrate P while moving it and while adjusting the state of movement of the substrate stage 2 holding the substrate P such that the positional relationship between the image plane of the projection optical system PL and the surface of the substrate P changes to the desired state. The surface positional information of the surface of the substrate P is detected by the focus and level detection system 18. The control apparatus 3 compensates the results of detection of the surface positional information of the surface of the substrate P by the focus and level detection system 18, based on the surface positional information of the pattern-formed surface MA of the mask M, and based on this correction value, it controls the substrate stage 2 and exposes the substrate P while adjusting the position of the surface of the substrate P.

As described above, by detecting beforehand the surface positional information of the pattern-formed surface MA′ of the reference mask M′, and by determining beforehand the second correction value for exposing the substrate P in the desired state using the reference mask M′, the surface positional information of the pattern-formed surface MA of the mask M for device manufacture can be acquired accurately and with good efficiency, and the substrate P can be satisfactorily exposed.

When the surface positional information of the pattern-formed surface MA of the mask M and the projection state of the pattern image is associated to determine the first correction value for exposing the substrate P satisfactorily in the desired state using the surface positional information of the pattern-formed surface MA of the mask M for device manufacture, operations to acquire the projection state of the pattern image using the mask M, such as test exposure of the substrate P must be performed. Generally, a plurality of pattern images are sequentially projected on the substrate P using a plurality of masks M to manufacture the device, but when the operation to acquire the surface positional information of the pattern-formed surface MA of the mask M and the operation to acquire the projection state of the pattern image using the mask M (operation to implement test exposure) are carried out, the utilization rate of the exposure apparatus EX may degrade. In the present embodiment, the operation to acquire the projection state of the pattern image (operation to implement test exposure) may be implemented for the specified number of times (once in the present embodiment) using the reference mask M′ without causing degradation in the utilization rate of the exposure apparatus EX, and the substrate P can be exposed satisfactorily and with good efficiency using the mask M for device manufacture. The operation to acquire the projection state of the pattern image using the reference mask M′ is not limited to test exposure only; for example, it may be acquired by aerial image measurement using photoelectric sensor. Details of aerial image measurement are disclosed for example, in the Japanese Unexamined Patent Application, First Publication No. 2002-14005.

Also, not only a semiconductor wafer for semiconductor device manufacture can be used as the substrate P in the first and second embodiments mentioned above, but also a glass substrate for liquid crystal display devices, a ceramic wafer for thin film magnetic heads, or an original wafer (synthetic quartz, silicone wafer) of mask or reticle used in exposure apparatuses or a film member may be used. The substrate is not limited to circular shape; rectangular or other shapes may be used.

In addition to using the scanning type exposure apparatus (scanning stepper) based on the step and scan method that scans and exposes the pattern of mask M after synchronously moving the mask M and substrate P, a scanning type exposure apparatus (stepper) based on the step and repeat method that exposes the pattern of mask M in a batch with the substrate P and the mask M maintained in the static state and sequentially moves the substrate P in steps, may also be used as the exposure apparatus EX.

An exposure apparatus that performs batch exposure on the substrate P of the reduction image of the first pattern in the substantially static state of the first pattern and the substrate P using a projection optical system (such as a dioptric projection optical system that does not include reflecting elements at a reduction magnification of ⅛) may be used as the exposure apparatus EX. In this case, subsequently, a switching type batch exposure apparatus that performs batch exposure on the substrate P by overlapping the reduction image of the second pattern in the substantially static state of the second pattern and the substrate P with a part of the first pattern using this projection optical system may also be used. A step and stitch type exposure apparatus that sequentially moves the substrate P and partially overlaps and transfers at least two patterns on to the substrate P may be used as the switching type exposure apparatus.

Moreover, the present invention may also be used in a multi-stage type exposure apparatus provided with a plurality of substrate stages, as disclosed, for example, in the Japanese Unexamined Patent Application, First Publication No. H10-163099, Japanese Unexamined Patent Application, First Publication No. H10-214783, Published Japanese Translation No. 2000-505958 of PCT International Publication.

Furthermore, the exposure apparatus EX according to each of the embodiments mentioned above, may be provided with a measurement stage that is moved independently from the substrate stage holding the substrate, and is equipped with measurement members (for example, reference member formed with reference marks and/or various kinds of photoelectric sensor), as disclosed, for example, in the Japanese Unexamined Patent Application, First Publication No. H11-135400 (corresponding to International Patent Application No. 1999/23692) and the Japanese Unexamined Patent Application, First Publication No. 2000-164504 (corresponding to U.S. Pat. No. 6,987,963). The exposure apparatus provided with this measurement stage may have the measurement stage wherein a plurality of measurement members including aerial image measurement instrument mentioned above are all installed, but with at least one of the plurality of measurement members installed in the substrate stage.

In other embodiments, electronic mask that generates variable patterns (also called variable pattern forming mask, active mask or pattern generator) may be used. For example, a deformable micro-mirror device or digital micro-mirror device (DMD), which is a kind of non-radiative type image display element (also called spatial light modulator (SLM)) may be used as the electronic mask. The DMD has a plurality of reflecting elements (micro-mirrors) that are driven based on specified electronic data. The plurality of reflecting elements are arranged in a two-dimensional matrix form on the surface of the DMD, are driven in element units, and they reflect and deflect the exposure light. The angle of the reflecting surface of each reflecting element can be adjusted. The operation of the DMD is controlled by the control apparatus. The control apparatus drives the reflecting elements of each DMD and forms patterns of the exposure light shone by the illumination system using the reflecting elements, based on the electronic data (pattern information) corresponding to patterns to be formed on the substrate. By using DMD, mask alignment operations in the mask stage and during the mask replacement work are not required when the pattern is changed, in contrast to the case when exposure is performed using mask (reticle) on which pattern is formed. A mask stage is not installed in an exposure apparatus using electronic mask; the substrate may merely be moved in the X-axis and the Y-axis directions by the substrate stage. Moreover, to adjust the relative position of the pattern image on the substrate, the relative position of the electronic mask that generates the patterns may be adjusted by an actuator and the like. The exposure apparatus using DMD is disclosed, for example, in the Japanese Unexamined Patent Application, First Publication No. H08-313842, Japanese Unexamined Patent Application, First Publication No. 2004-304135, and U.S. Pat. No. 6,778,257.

Moreover, the present invention can also be used in a liquid immersion type exposure apparatus that exposes the substrate in a state wherein the light path of exposure light is filled with liquid, as disclosed in PCT International Publication No. WO 99/49504 and Japanese Unexamined Patent Application, First Publication No. 2004-289126 (corresponding to U.S. Patent Application, Publication No. 2004/0165159). The liquid immersion system, for instance, may be installed in the neighborhood of the light path of the exposure light between the front optical element of the projection optical system and the substrate, and it may have a supply member with a supply port for supplying liquid for the light path and a recovery member having a recovery port for recovery of liquid. There is no need for a part (for example, liquid supply member and/or liquid recovery member) of the liquid immersion system to be installed in the exposure apparatus. For example, equipment in a plant wherein the exposure apparatus is installed, may be used instead. The construction of the liquid immersion system is not limited to the construction described above. For instance, the construction mentioned in the European Patent Application, Publication No. 1420298, PCT International Publication No. WO 2004/055803, PCT International Publication No. WO 2004/057590, PCT International Publication No. WO 2005/029559 (corresponding to U.S. Patent Application, Publication No. 2006/0231206), PCT International Publication No. WO 2004/086468 (corresponding to U.S. Patent Application, Publication No. 2005/0280791), and the Japanese Unexamined Patent Application, First Publication No. 2004-289126 (corresponding to U.S. Pat. No. 6,952,253) may be used.

Water (pure water) may be used as the liquid in the liquid immersion method. Other than water, perfluoropolyether (PFPE), fluorine-based fluids such as fluorine-based oil, or cedar oil may be used. A liquid with higher refractive index for the exposure light than water, such as a liquid with a refractive index of about 1.6 to 1.8 may be used. As liquid LQ with a refractive index higher than that of pure water (for example greater than 1.5), specific liquids with C—H bonds or O—H bonds such as isopropanol with refractive index of about 1.50, glycerol (glycerine) with refractive index of about 1.61, specific liquids (organic solvents) such as hexane, heptane, decane, or Decalin (Decahydronaphthalene) with refractive index of about 1.60 may be used. The liquid LQ may also be a combination of two or more kinds of any of the liquids mentioned above, or it may be any one of these liquids added (mixed) with pure water. Furthermore, the liquid LQ may be pure water with base or acid such as H⁺,Cs⁺,K⁺,Cl⁻,SO4²⁻,PO4²⁻ added (mixed) to it, or may be pure water with fine particles of Al oxide added (mixed) to it. The liquid used should preferably have a small light absorption coefficient, less temperature dependency, and stability of photosensitive material (or top coat film or reflection preventing film, and so on) coated on the surface of the projection optical system and/or the substrate. A supercritical fluid may also be used as the liquid. A top coat film and the like to protect the photosensitive material and base material from the liquid may be provided on the substrate. The front optical element may be formed of single crystals of silica or fluorine compounds such as calcium fluoride (fluorite), barium fluoride, strontium fluoride, lithium fluoride, and sodium fluoride, or it may be formed of a material with higher refractive index (greater than 1.6, for example) than silica or fluorite. Sapphire, germanium dioxide, and so on disclosed in PCT International Publication No. WO 2005/059617, or potassium chloride (refractive index of about 1.75) disclosed in International Publication No. WO 2005/059618, may be used material with refractive index greater than 1.6.

When the liquid immersion method is used, in addition to the light path on the image plane side of the front optical element, the light path on the objective plane side of the front optical element may also be filled with liquid, as disclosed in PCT International Publication No. WO 2004/019128 (corresponding to U.S. Patent Application, Publication No. 2005/0248856). Moreover, a lyophilic thin film and/or thin film with function to prevent dissolution may be formed on the complete surface of the front optical element or part thereof (including the contact surface with at least the liquid). Silica has good affinity with the liquid and does not require film to prevent dissolution, but at least a film to prevent dissolution should preferably be formed in case of fluorite.

In the embodiment mentioned above, the positional information of the mask stage and the substrate stage was measured using an interferometer system. However, the invention is not limited to this system, and an encoder system that detects the scale (diffraction grating) installed on the upper surface of the substrate stage, for example, may also be used. In this case, a hybrid system provided with both interferometer system and encoder system should preferably be used, and the measurement results of the encoder system should be calibrated using the measurement results of the interferometer system. The position control of the substrate stage may be performed using the interferometer system and encoder system by switching over between the two systems or using both the systems.

The exposure apparatus EX is not limited to exposure apparatus for manufacture of semiconductor elements that expose semiconductor element patterns on the substrate P; it can be generally applied to various kinds of exposure apparatuses such as exposure apparatus used for the manufacture of liquid-crystal display elements or displays, and exposure apparatus used for the manufacture of thin film magnetic heads, image pickup elements (CCD), micro-machines, MEMS, DNA chips, or reticles or masks, and so on.

As far as is permitted, the disclosures in all of the Patent Publications and U.S. patents related to exposure apparatuses and the like cited in the above respective embodiments and modified examples, are incorporated herein by reference.

As described above, the exposure apparatus EX of the embodiment mentioned above, is produced by assembling each of the sub-systems that contain each of the constituent features so as to maintain a predetermined mechanical precision, electrical precision and optical precision. To ensure each of these precisions, adjustments for achieving optical precision for each kind of optical system, adjustments for achieving mechanical precision for each kind of mechanical system, and adjustments for achieving electrical precision for each kind of electrical system are carried out before and after assembly. The process of assembling the exposure apparatus from each sub-system includes mutual mechanical connections, electrical circuit wiring connections, and pneumatic circuit line connections and the like, between the various sub-systems. It will be understood, of course, that the steps of assembling the individual sub-systems come before the step of assembling the exposure apparatus from the various sub-systems. Once the process of assembling the various sub-systems into the exposure apparatus is completed, overall adjustment is performed, so as to achieve the various precisions as an overall exposure apparatus. Furthermore, it is desirable that the exposure apparatus be manufactured in a clean room with a controlled temperature and level of cleanness.

As shown in FIG. 16, microdevice such as semiconductor devices are produced by such steps such as step 201 of designing the functions and performance of the microdevice, step 202 of manufacturing a mask (reticle) based on the design step; step 203 of producing a substrate which is the base material of the device, step 204 including substrate treatment processes such as the process of exposing the mask pattern on the substrate by the exposure apparatus EX of the embodiment mentioned above, the process of developing the exposed substrate, the heating (curing) and etching process of the developed substrate, step 205 of assembling the device (including processes such as dicing, bonding, and packaging), and step 206, which is the inspection step.

According to the aspects of the present invention, the surface positional information of surface with mask pattern formed thereon can be acquired with good efficiency and precision; the substrate can be satisfactorily exposed with the acquired data, and a device with the desired performance can be produced.

1. An exposure method comprising:
detecting, based on a reception result of a detection light from a reference surface on which the detection light is directed, a first information including a surface positional information of the reference surface;
detecting, based on a reception result of the detection light from a first surface of a first mask on which a pattern is formed, a second information including a surface positional information of the first surface, the first surface including a plurality of areas each on which the detection light is directed, the detection of the second information being executed for respective the areas, the detection of the first information being executed before the detection for the areas; and
exposing a substrate with the pattern of the first mask.

2. The exposure method according to claim 1, wherein,
the exposure comprises irradiating the first mask held by a predetermined holding member, with an exposure light, and
the detection of the second information comprises directing the detection light to the first surface of the first mask held by the holding member.

3. The exposure method according to claim 1, further comprising:
acquiring relative surface positional information between the reference surface and the first surface, based on the detection results of the first information and the second information.

4. The exposure method according to claim 1, wherein
the detection of the second information comprises
detecting the second information of a first area of the first surface while moving the first mask along a first direction in a specified plane substantially parallel to the first surface, and
detecting the second information of a second area of the first surface, the second area positioned lateral to the first area in a second direction intersecting the first direction.

5. The exposure method according to claim 4, wherein the second information is detected while moving a directing position of the detection light slightly at an inclination with the first direction in the specified plane.

6. The exposure method according to claim 5, wherein the detection of the second information comprises slightly moving the detection light in a small area of the first surface, and determining a mean value of surface position within the small area based on the reception result of the detection light.

7. The exposure method according to claim 1, wherein, in the detection of the first information and the detection of the second information, the detection light is directed on respective the areas via respectively corresponding one among a plurality of optical systems.

8. The exposure method according to claim 1, wherein the exposure comprises adjusting an exposure condition based on the second information.

9. The exposure method according to claim 8, wherein
the exposure further comprises
obtaining a first correction value for exposing the substrate via the first mask in desired state, based on the second information, and
adjusting the exposure condition based on the first correction value.

10. The exposure method according to claim 1, wherein the reference surface from which the first information is detected is formed on the first mask.

11. The exposure method according to claim 10, further comprising:
obtaining a reference correction value for exposing the substrate in desired state by means of a reference mask, the reference mask being different from the first mask and having the reference surface from which the first information is detected and on which a pattern is formed, wherein
the first correction value is determined based on the first information, the second information, and the reference correction value.

12. An exposure method comprising:
detecting a first information including surface positional information of a reference surface of a reference mask whereupon a pattern is formed;
obtaining a reference correction value for exposing a substrate in desired state via the reference mask;
detecting a second information including surface positional information of a first surface of a first mask;
obtaining a first correction value for exposing the substrate in desired state via the first mask based on the first information, the second information, and the reference correction value; and
exposing the substrate with pattern formed on the first surface of the first mask based on exposure condition adjusted based on the first correction value.

13. The exposure method according to claim 11, wherein
the first information is stored beforehand in a storage apparatus,
the first correction value is determined based on the stored first information and the detected second information.

14. The exposure method according to claim 13, wherein
information related to the first correction value corresponding to the reference correction value is stored beforehand in the storage apparatus, according to the difference between the surface position of the reference surface and the surface position of the first surface
the first correction value is determined based on the detected second information and the stored data in the storage apparatus, and the exposure condition is adjusted based on the determined first correction value.

15. The exposure method according to claim 9, wherein the substrate is exposed while moving the substrate in the predetermined direction and while adjusting the exposure condition based on the first correction value.

16. The exposure method according to claim 8, wherein the exposure condition includes at least either a relative distance or a relative inclination of the substrate surface with respect to the first surface of the first mask.

17. The exposure method according to claim 8, further comprising:
detecting surface positional information of a surface of the substrate, wherein
the exposure comprises correcting a detection result of the surface positional information of the substrate based on the first information, and adjusting position of the surface of the substrate based on the corrected information.

18. The exposure method according to claim 8, wherein
an image of the pattern of the first mask is projected on the surface of the substrate via a projection optical system, and
the exposure condition includes an imaging characteristic of the projection optical system.

19. A device manufacturing method using the exposure method according to claim 1.

20. An exposure apparatus that exposes a substrate with a pattern formed on a first surface of a first mask, the exposure apparatus comprising:
a holding member that holds the first mask;
a first detection apparatus that directs a detection light onto a specified area of the first surface of the first mask held by the holding member via a first opening formed on the holding member and can detect surface positional information of the area based on a reception result of the detection light from the first surface, and directs the detection light onto a specified reference surface and can detect surface positional information of the reference surface based on a reception result of the detection light from the reference surface; and
a control apparatus that controls the first detection apparatus to detect surface positional information of each of a plurality of areas of the first surface, and controls the detecting operation for the reference surface with the first detection apparatus such that the detecting operation is implemented in each detecting operation for the areas before the detecting operation for the areas.

21. The exposure apparatus according to claim 20, further comprising:
a base having a second opening through which an exposure light passes and a third opening different from the second opening; and
a drive device that drives the holding member on the base, wherein
the first detection apparatus directs the detection light on the first surface through the third opening of the base and the first opening of the holding member.

22. The exposure apparatus according to claim 21, wherein the control apparatus directs the detection light on the first surface through the third opening and the first opening and detects the surface positional information of the first area on the first surface, while moving the holding member within the specified area including the third opening on the base along a first direction then moves the directing position of the detection light along a second direction intersecting the first direction; thereafter, directs the detection light on the first surface through the third opening and the first opening and detects the surface positional information of a second area different from the first area on the first surface while moving the holding member within the specified area along the first direction, and implements the detecting operation for the reference surface before implementing the operation to detect the surface positional information of the first area, and the operation to detect the surface positional information of the second area respectively.

23. The exposure apparatus according to claim 22, wherein
the second opening and the third opening are formed side by side in the first direction; and
the first mask is exposed while moving it along the first direction.

24. The exposure apparatus according to claim 20, wherein the first detection apparatus acquires relative surface positional information of the first surface with respect to the reference surface, based on the detection results for the reference surface and the first surface.

25. The exposure apparatus according to claim 20, wherein
the first detection apparatus comprises
an emitting surface that emits the detection light,
a plurality of first optical systems each installed to correspond to each of the plurality of areas; and
a second optical system that leads the detection light emitted from a specified position of the emitting surface to a first optical system that corresponds to the area to be detected from among the plurality of first optical systems.

26. The exposure apparatus according to claim 20, further comprising an alarm device that emits alarm according to the detection result of the first detection apparatus.

27. The exposure apparatus according to claim 20, further comprising an adjusting device that adjusts an exposure condition based on the detection result of the first detection apparatus.

28. An exposure apparatus that exposes a substrate with a pattern formed on a first surface of a first mask, the exposure apparatus comprising:
a first detection apparatus that detects surface positional information of the first surface of the first mask;
a first storage apparatus that pre-stores surface positional information of a second surface whereupon a pattern of a second mask different from the first mask is formed;
a second storage apparatus that pre-stores a second correction value for exposing the substrate in desired state using the second mask; and
a control apparatus that determines a first correction value for exposing the substrate in desired state using the first mask based on the detection result of the first detection apparatus, the stored information in the first storage apparatus, and the stored information in the second storage apparatus.

29. A device manufacturing method using the exposure apparatus according to claim 20.
